(19) United States
(12) Patent Application Publication
(10) Pub. No.: US 2025/0048706 A1
(43) Pub. Date: Feb. 6, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Tsung-Jui WU, Tainan City (TW); Tsung-Yin HSU, Tainan City (TW); Ying Ming WANG, Tainan City (TW); Shih-Hao CHEN, Zhubei City (TW); Sung-Hsin YANG, Tainan (TW)

(21) Appl. No.: 18/500,896

(22) Filed: Nov. 2, 2023

Related U.S. Application Data
(60) Provisional application No. 63/517,786, filed on Aug. 4, 2023.

(51) Int. Cl. H01L 29/66; H01L 21/8238; H01L 27/092; H01L 29/06; H01L 29/423; H01L 29/775; H01L 29/78

(52) U.S. Cl. CPC H01L 29/6656; H01L 21/823807; H01L 21/823814; H01L 21/823821; H01L 21/823864; H01L 27/0924; H01L 29/0673; H01L 29/42392; H01L 29/66439; H01L 29/66545; H01L 29/66795; H01L 29/775; H01L 29/7851

(57) ABSTRACT

A sidewall protection layer is formed on sidewall spacers of a dummy gate structure of a semiconductor device prior to etching an underlying fin structure to form a source/drain recess. The sidewall protection layer enables the profile of the source/drain recess to be precisely controlled so that etching into residual dummy gate material near the source/drain recess is minimized or prevented. The sidewall protection layer may be removed or retained in the semiconductor device after formation of the source/drain recess. The sidewall protection layer reduces the likelihood of the source/drain regions of the semiconductor device contacting the metal gate structures of the semiconductor device after the dummy gate structures are replaced with the metal gate structures. Thus, the sidewall protection layer reduces the likelihood of electrical shorting between the source/drain regions and the metal gate structures.

### CROSS-REFERENCE TO RELATED APPLICATION

This Patent application claims priority to U.S. Provisional Patent Application No. 63/517,786, filed on Aug. 4, 2023, and entitled “SEMICONDUCTOR DEVICE AND METHODS OF FORMATION.” The disclosure of the prior Application is considered part of and is incorporated by reference into this Patent Application.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions. Source/drain regions (e.g., epitaxial regions) are located on opposing sides of the gate structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of example regions of a semiconductor device described herein.

FIGS. 3A-3D are diagrams of an example implementation described herein.

FIGS. 4A-4G are diagrams of an example implementation described herein.

FIGS. 5A-5D are diagrams of an example implementation described herein.

FIGS. 6A-6C are diagrams of an example implementation described herein.

FIGS. 7A-7D are diagrams of an example implementation described herein.

FIGS. 8A-8H are diagrams of an example implementation described herein.

FIG. 9 is diagram of an example implementation described herein.

FIGS. 10A-10C are diagrams of an example implementation described herein.

FIG. 11 is a diagram of example components of a device described herein.

FIG. 12 is a flowchart of an example process associated with forming a semiconductor device described herein.

FIG. 13 is a flowchart of an example process associated with forming a semiconductor device described herein.

FIG. 14 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the fabrication of fin-based transistors, dummy gate structures may be formed as sacrificial structures that are subsequently removed in a later processing stage and replaced with metal gate structures that include high dielectric constant (high-k) dielectrics and/or metal layers. The dummy gate structures enable other layers and/or structures to be formed prior to formation of the metal gate structures, such as source/drain regions of the fin-based transistors. Source/drain region(s) may refer to a source or a drain, individually or collectively dependent upon the context. The dummy gate structures preserve the space in which the metal gate structures are to be formed, as well as take on the processing damage from forming the other layers and/or structures. The metal gate structures are therefore subjected to less processing damage than if the metal gate structures were formed at an earlier stage in the fabrication process of fabricating the fin-based transistors.

A dummy gate structure may be formed by depositing one or more layers such as a polysilicon (PO) layer, forming a pattern in one or more masking layers using photolithography, and etching the one or more layers based on the pattern. In some cases, residual dummy gate material remains after the dummy gate structure is formed. The residual dummy gate material may result in formation of defects in the fin-based transistors that cause electrical shorting between the source/drain regions of the fin-based transistors and the metal gate structures of the fin-based transistors. For example, when etching fin structures of the fin-based transistors to form source/drain recesses in which the source/drain regions are to be formed, the residual dummy gate material may be exposed in the source/drain recesses. As a result, the source/drain regions formed in the source/drain recesses may be in contact with the residual dummy gate material. When the dummy gate structures are replaced with the metal gate structures in a replacement gate process (RPG), the residual dummy gate material is also removed and replaced with metal material, resulting in contact (and electrical shorting) between the metal gate structures and the source/drain regions.

In some implementations described herein, a sidewall protection layer is formed on sidewall spacers of a dummy gate structure of a semiconductor device prior to etching an underlying fin structure to form a source/drain recess (e.g., a strained source/drain recess (SSD)). The sidewall protection layer enables the profile of the source/drain recess to be precisely controlled so that etching into residual dummy gate material near the source/drain recess is minimized or prevented. The sidewall protection layer may be removed or retained in the semiconductor device after formation of the source/drain recess.

In this way, the sidewall protection layer reduces the likelihood of the source/drain regions of the semiconductor device contacting the metal gate structures of the semiconductor device after the dummy gate structures are replaced with the metal gate structures. Thus, the sidewall protection layer reduces the likelihood of electrical shorting between the source/drain regions and the metal gate structures. This may reduce the rate and/or likelihood of defect formation in the semiconductor device and/or may increase the yield of fin-based transistors in the semiconductor device, among other examples.

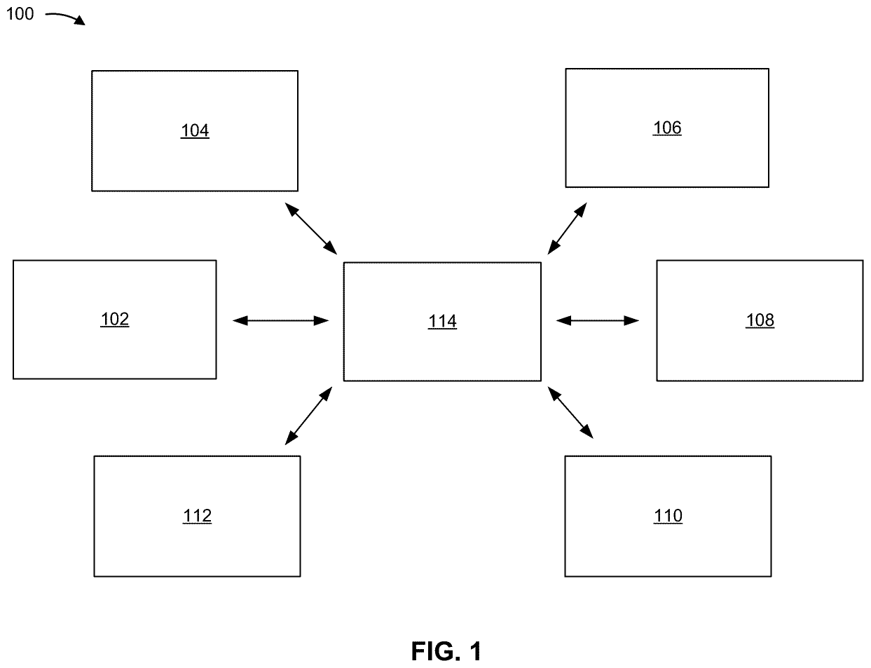

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples. The deposition tool 102 is a semiconductor processing tool that includes a

semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-112 may perform one or more semiconductor processing operations described herein. For example, one or more of the semiconductor processing tools 102-112 may form a fin structure above a substrate of a semiconductor device; may form a dummy gate structure that wraps around the fin structure on at least three sides of the fin structure; may form a sidewall protection layer on a sidewall spacer layer of the dummy gate structure; may remove a portion of the fin structure adjacent to the dummy gate structure to form a source/drain recess, where the sidewall protection layer resists etching of the fin structure under the sidewall spacer layer; and/or may form a source/drain region in the source/drain recess, among other examples.

As another example, one or more of the semiconductor processing tools 102-112 may form a fin structure above a substrate of a semiconductor device; may form a dummy gate structure that wraps around the fin structure on at least three sides of the fin structure; form a sidewall protection layer on a sidewall spacer layer of the dummy gate structure; may remove a portion of the fin structure adjacent to the dummy gate structure to form a source/drain recess, where the sidewall protection layer resists etching of the fin structure under the sidewall spacer layer; may remove at least a portion of the sidewall protection layer after forming the source/drain recess; and/or may form a source/drain region in the source/drain recess, among other examples.

As another example, one or more of the semiconductor processing tools 102-112 may form a fin structure above a substrate of a semiconductor device; may form a dummy gate structure that wraps around the fin structure on at least three sides of the fin structure; may remove a first portion of the fin structure adjacent to a first side of the dummy gate structure to form a first source/drain recess to a first depth; may remove a second portion of the fin structure adjacent to a second side of the dummy gate structure, opposing the first side, to form a second source/drain recess to a second depth that is greater than the first depth; may form a first sidewall protection layer on the first side of the dummy gate structure, where the first sidewall protection layer extends into the first source/drain recess; may form a second sidewall protection layer on the second side of the dummy gate structure, where the second sidewall protection layer extends into the second source/drain recess to a lower depth in the semiconductor device than the first sidewall protection layer; may remove a third portion of the fin structure to increase the first source/drain recess from the first depth to a third depth, where the first sidewall protection layer resists etching of the fin structure under the first sidewall spacer layer; may remove a fourth portion of the fin structure to increase the second source/drain recess from the second depth to a fourth depth, where the second sidewall protection layer resists etching of the fin structure under the second sidewall spacer layer; may form a first source/drain region in the first source/drain recess; and/or may form a second source/drain region in the second source/drain recess, among other examples.

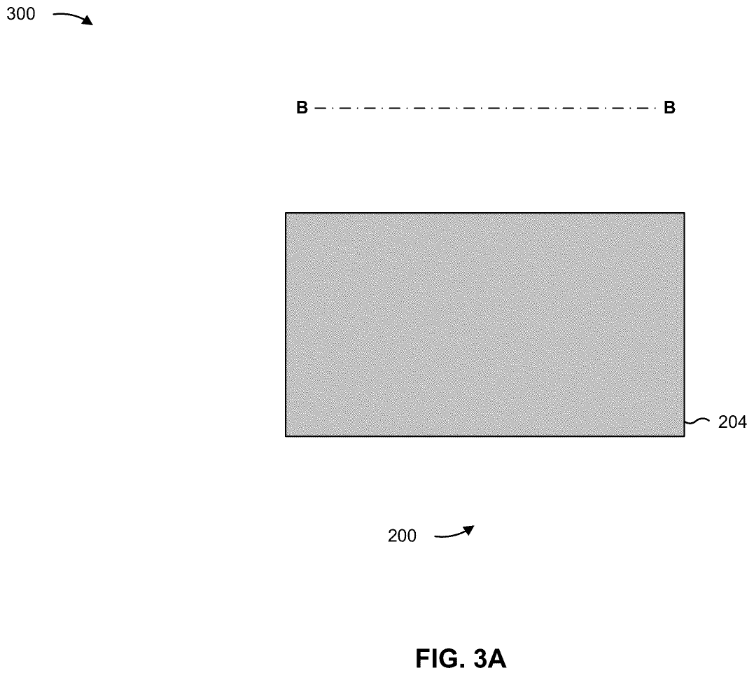

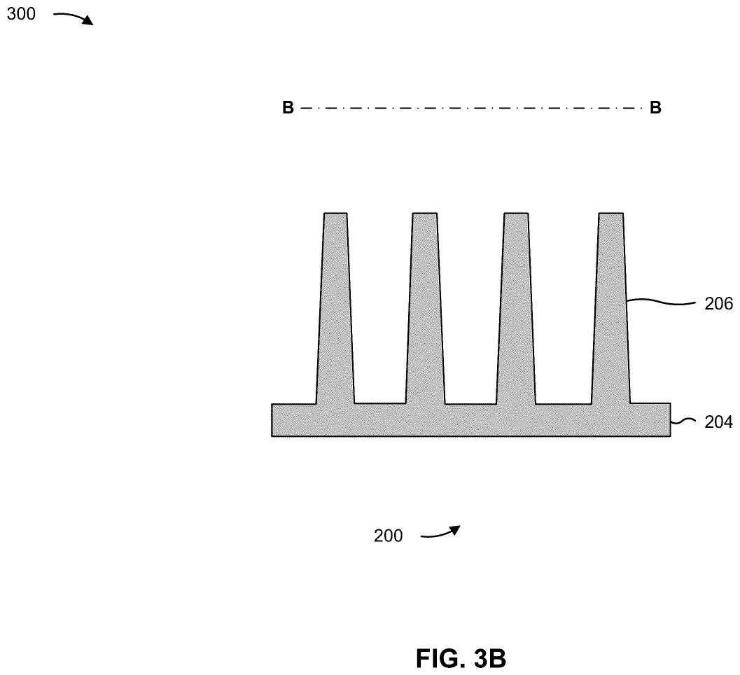

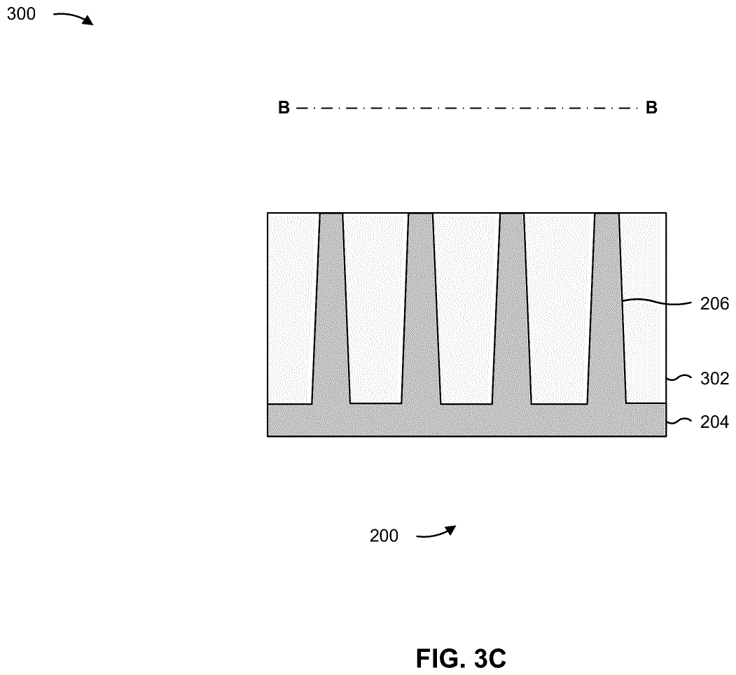

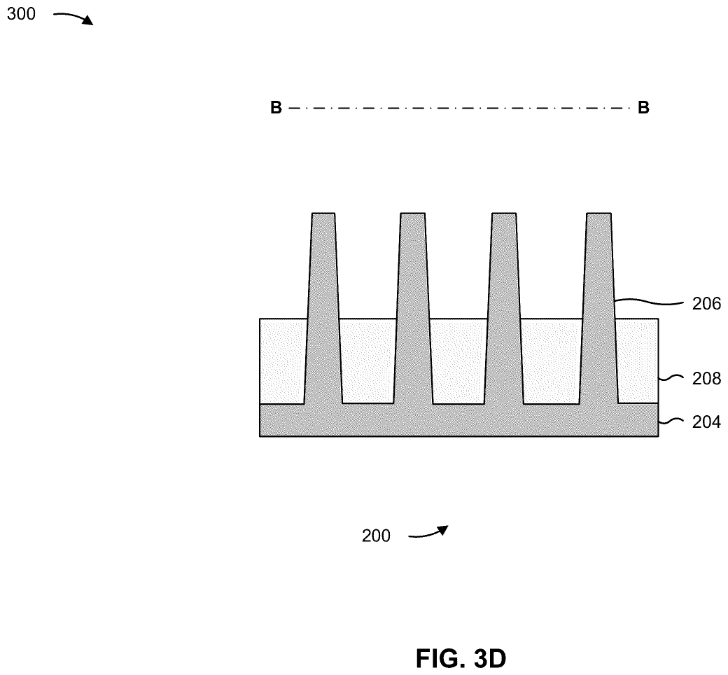

One or more of the semiconductor processing tools 102-112 may perform other semiconductor processing operations described herein, such as in connection with FIGS. 3A-3D, 4A-4G, 5A-5D, 6A-6C, 7A-7D, 8A-8H, 10A-10C, 12, and/or 13, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment

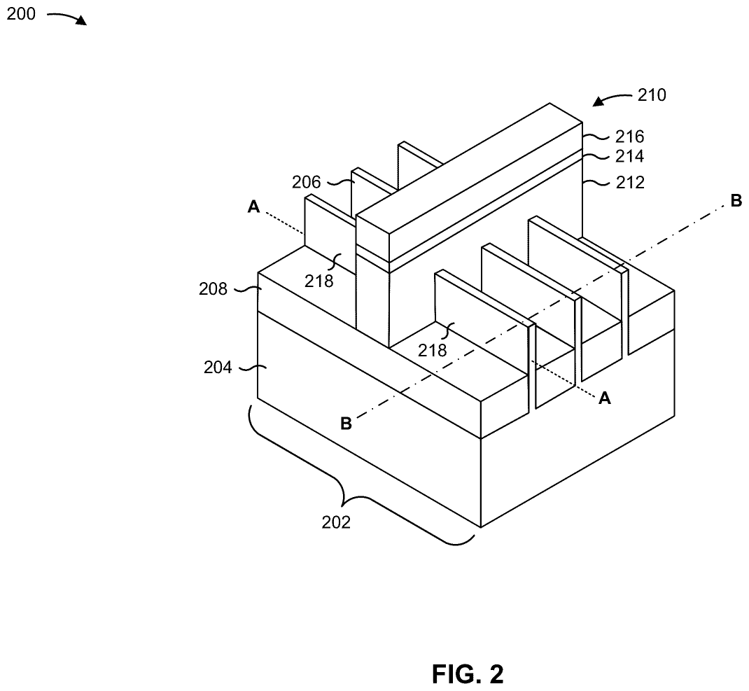

FIG. 2 is a diagram of example regions of a semiconductor device 200 described herein. In particular, FIG. 2 illustrates an example device region 202 of the semiconductor device 200 in which one or more transistors or other devices are included. The transistors may include fin-based transistors, such as fin field effect transistors (finFETs), nanostructure transistors, and/or other types of transistors. In some implementations, the device region 202 includes a p-type metal oxide semiconductor (PMOS) region, an n-type metal oxide semiconductor (NMOS) region, a complementary metal oxide semiconductor (CMOS) region, and/or another type of device region. FIGS. 3A-7D are schematic cross-sectional views of various portions of the device region 202 of the semiconductor device 200 illustrated in FIG. 2, and correspond to various processing stages of forming fin-based transistors in the device region 202 of the semiconductor device 200.

The semiconductor device 200 includes a substrate 204. The substrate 204 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, or another type of semiconductor substrate. The substrate 204 may include a round/circular substrate having an approximately 200 mm diameter, an approximately 300 mm diameter, or another diameter, such as 450 mm, among other examples. The substrate 204 may alternatively be any polygonal, square, rectangular, curved, or otherwise non-circular workpiece, such as a polygonal substrate.

Fin structures 206 are included above (and/or extend above) the substrate 204 for the device region 202. A fin structure 206 may provide an active region where one or more devices (e.g., fin-based transistors) are formed. In some implementations, the fin structures 206 include silicon (Si) materials or another elementary semiconductor material such as germanium (Ge). In some implementations, the fin structures 206 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof. In some implementations, the fin structures 206 are doped using n-type and/or p-type dopants.

The fin structures 206 are fabricated by suitable semiconductor process techniques, such as masking, photolithography, and/or etch processes, among other examples. As an example, the fin structures 206 may be formed by etching a portion of the substrate 204 away to form recesses in the substrate 204. The recesses may then be filled with isolating material that is recessed or etched back to form shallow trench isolation (STI) regions 208 above the substrate 204 and between the fin structures 206. Other fabrication techniques for the STI regions 208 and/or for the fin structures 206 may be used. The STI regions 208 may electrically isolate adjacent active areas in the fin structures 206. The STI regions 208 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The STI regions 208 may include a multi-layer structure, for example, having one or more liner layers.

A dummy gate structure 210 (or a plurality of dummy gate structures 210) is included in the device region 202 over the fin structures 206 (e.g., approximately perpendicular to the fin structures 206). The dummy gate structure 210 engages the fin structures 206 on three or more sides of the fin structures 206. In the example depicted in FIG. 2, the dummy gate structure 210 includes a gate electrode layer 212, a hard mask layer 214, and/or a capping layer 216, among other examples. In some implementations, the dummy gate structure 210 further includes a gate dielectric layer, one or more spacer layers, and/or another suitable layer. The various layers of the dummy gate structure 210 may be formed by suitable deposition techniques and patterned by suitable photolithography and etching techniques.

The term, “dummy”, as described here, refers to a sacrificial structure which will be removed in a later stage and will be replaced with another structure, such as a high dielectric constant (high-k) dielectric and metal gate structure in a replacement gate process. The replacement gate process refers to manufacturing a gate structure at a later stage of the overall gate manufacturing process. Accordingly, the configuration of the semiconductor device 200 illustrated in FIG. 2 may include an intermediate configuration, and additional semiconductor processing operations may be performed for the semiconductor device 200 to further process the semiconductor device 200.

The gate electrode layer 212 may include a polysilicon (PO) material or another suitable material. The gate electrode layer 212 may be formed by suitable deposition processes such as LPCVD or PECVD, among other examples. The hard mask layer 214 may include any material suitable to pattern the gate electrode layer 212 with particular features/dimensions on the substrate 204, such as a silicon nitride (SiₓN_{y}) among other examples. The capping layer 216 may include a dielectric oxide layer. The dielectric oxide layer may be formed by chemical oxidation, thermal oxidation, ALD, CVD, and/or other suitable methods.

In some implementations, the various layers of the dummy gate structure 210 are first deposited as blanket layers. Then, the blanket layers are patterned through a process including photolithography and etching processes, removing portions of the blanket layers and keeping the remaining portions over the STI regions 208 and the fin structures 206 to form the dummy gate structure 210.

Source/drain areas 218 are disposed in opposing regions of the fin structures 206 with respect to the dummy gate structure 210. The source/drain areas 218 include areas in the device region 202 in which source/drain regions are to be formed. The source/drain regions in the device region 202 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the device region 202 may include PMOS transistors that include p-type source/drain regions, NMOS transistors that include n-type source/drain regions, and/or other types of transistors.

Some source/drain regions may be shared between various transistors in the device region 202. In some implementations, various ones of the source/drain regions may be connected or coupled together such that fin-based transistors in the device region 202 are implemented as two functional transistors. For example, if neighboring (e.g., as opposed to opposing) source/drain regions are electrically connected, such as through coalescing the regions by epitaxial growth (e.g., neighboring source/drain regions, as opposed to on opposing sides of the dummy gate structure 210, being coalesced), two functional transistors may be implemented. Other configurations in other examples may implement other numbers of functional transistors.

FIG. 2 further illustrates reference cross-sections that are used in later figures, including FIGS. 3A-10C. Cross-section A-A is in a plane along a channel in a fin structure 206 between opposing source/drain areas 218. Cross-section B-B is in a plane perpendicular to cross-section A-A, and is across a source/drain area 218 in fin structure 206. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

FIGS. 3A-3D are diagrams of an example implementation 300 described herein. The example implementation 300 includes an example of forming fin structures 206 for transistors (e.g., finFETs, nanostructure transistors) in the device region 202 of the semiconductor device 200. FIGS. 3A-3D are illustrated from the perspective of the cross-sectional plane B-B in FIG. 2 for the device region 202. Turning to FIG. 3A, the example implementation 300 includes semiconductor processing operations relating to the substrate 204 in and/or on which transistors are formed in the device region 202.

As shown in FIG. 3B, the fin structures 206 are formed in the substrate 204 in the device region 202. In some implementations, a pattern in a photoresist layer is used to form the fin structures 206. In these implementations, the deposition tool 102 forms the photoresist layer on the substrate 204. The exposure tool 104 exposes the photoresist layer to a radiation source to pattern the photoresist layer. The developer tool 106 develops and removes portions of the photoresist layer to expose the pattern. The etch tool 108 etches into the substrate 204 to form the fin structures 206. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the fin structures 206 based on a pattern.

As shown in FIG. 3C, an STI layer 302 is formed in between the fin structures 206. The deposition tool 102 deposits the STI layer 302 using a CVD technique, a PVD technique, an ALD technique, a deposition technique described above in connection with FIG. 1, and/or another deposition technique. In some implementations, the STI layer 302 is formed to a height that is greater than the height of the fin structures 206. In these implementations, the planarization tool 110 performs a planarization (or polishing) operation to planarize the STI layer 302 such that the top surface of the STI layer 302 is substantially flat and smooth, and such that the top surface of the STI layer 302 and the top surface of the fin structures 206 are approximately the same height. The planarization operation may increase uniformity in the STI regions 208 that are formed from the STI layer 302 in a subsequent etch-back operation.

As shown in FIG. 3D, the STI layer 302 is etched in an etch back operation to expose portions of the fin structures 206. The etch tool 108 etches a portion of the STI layer 302 using a plasma etch technique, a wet chemical etch technique, and/or another type of etch technique. The remaining portions of the STI layer 302 between the fin structures 206 include the STI regions 208. In some implementations, the STI layer 302 is etched such that the height of the exposed portions of the fin structures 206 (e.g., the portions of the fin structures 206 that are above the top surface of the STI regions 208) and are the same height in the device region 202. In some implementations, a first portion of the STI layer 302 in the device region 202 is etched and a second portion of the STI layer 302 in the device region 202 is etched such that the height of exposed portions of a first subset of the fin structures 206 and the height of the exposed portions of a second subset of the fin structures 206 are different, which enables the fin heights to be tuned to achieve particular performance characteristics for the device region 202.

As indicated above, FIGS. 3A-3D are provided as an example. Other examples may differ from what is described with regard to FIGS. 3A-3D.

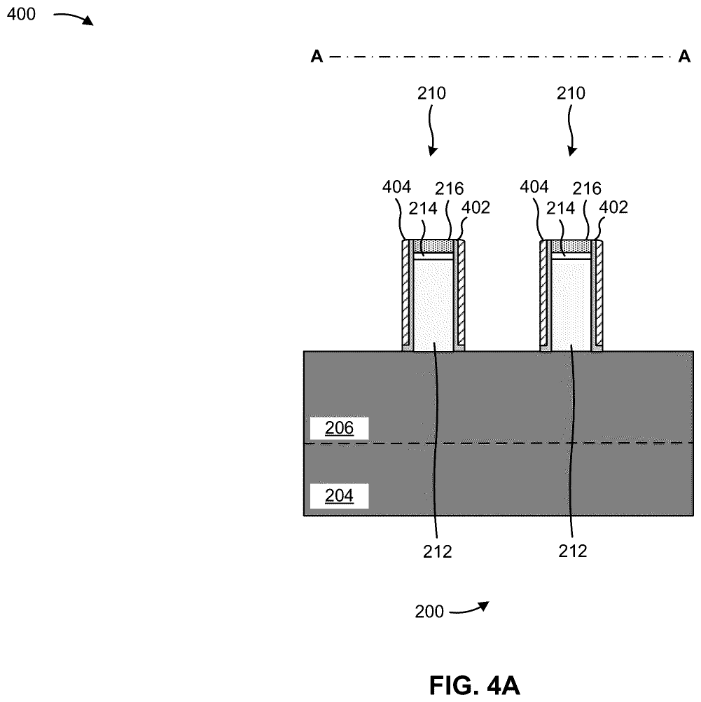

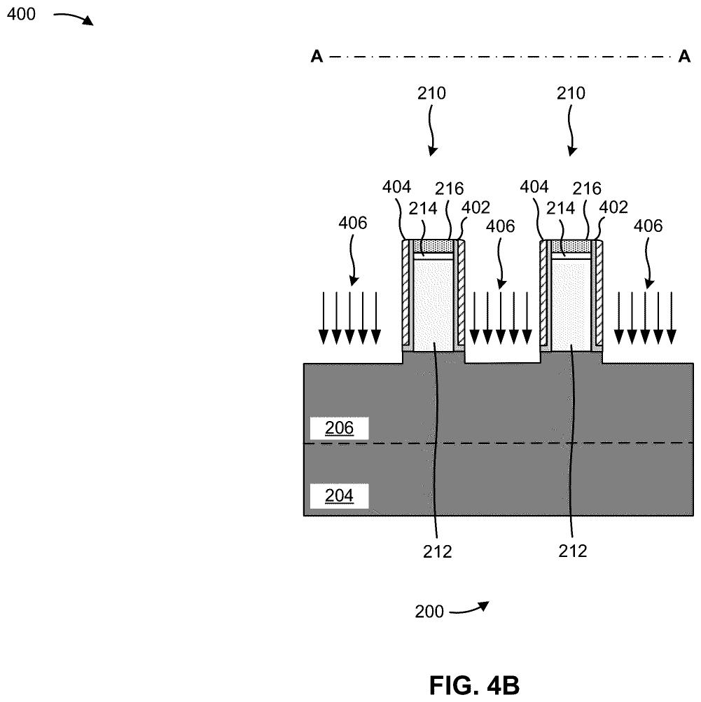

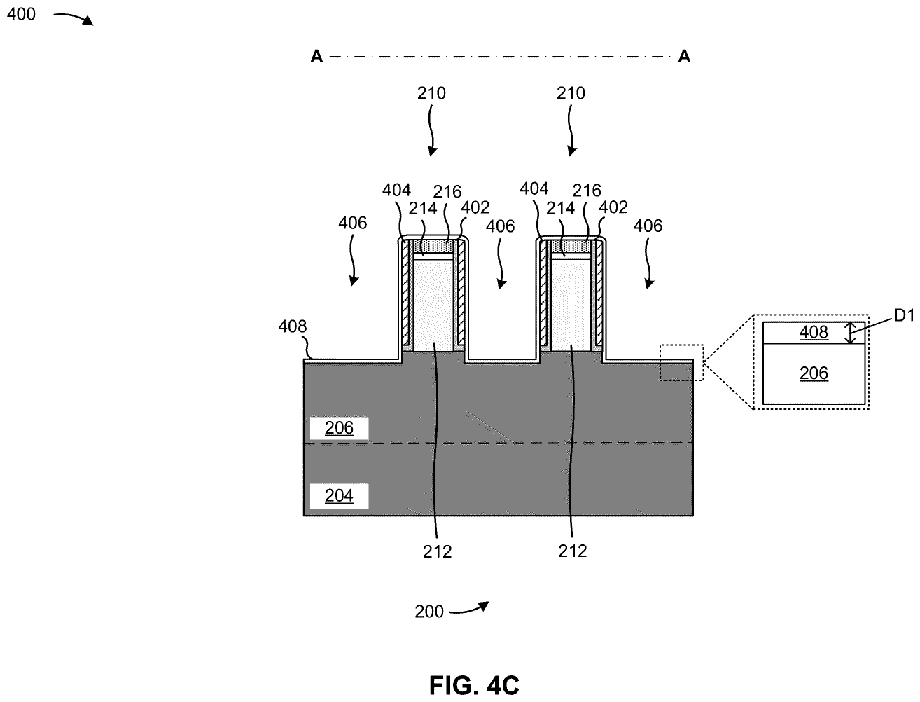

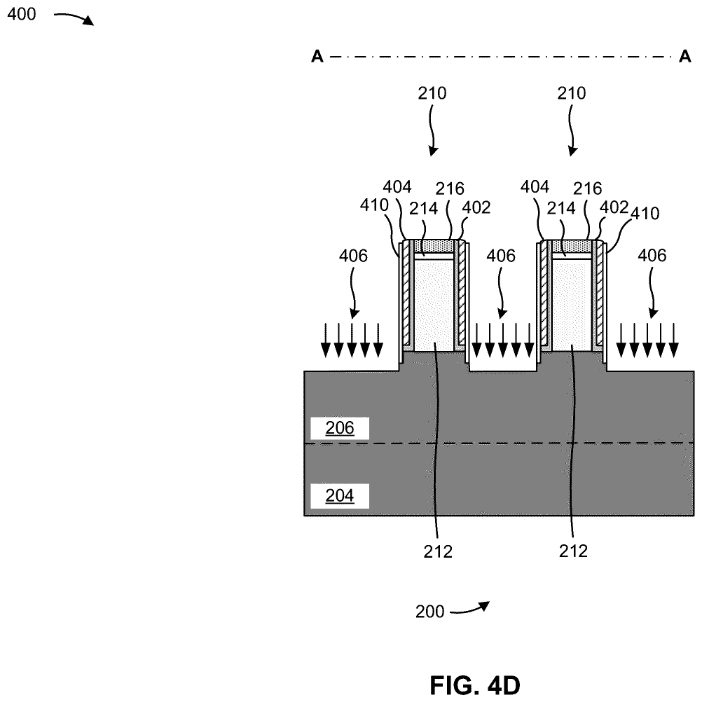

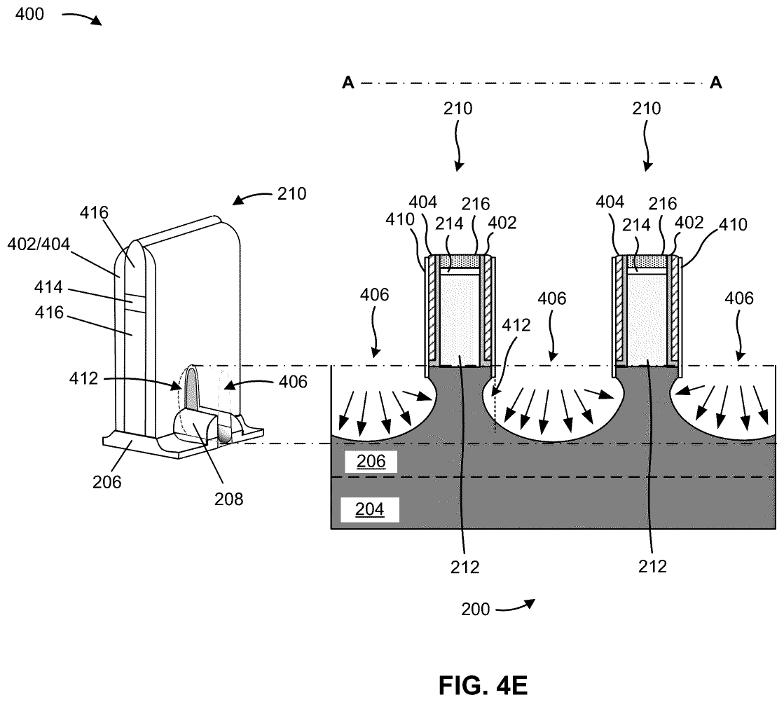

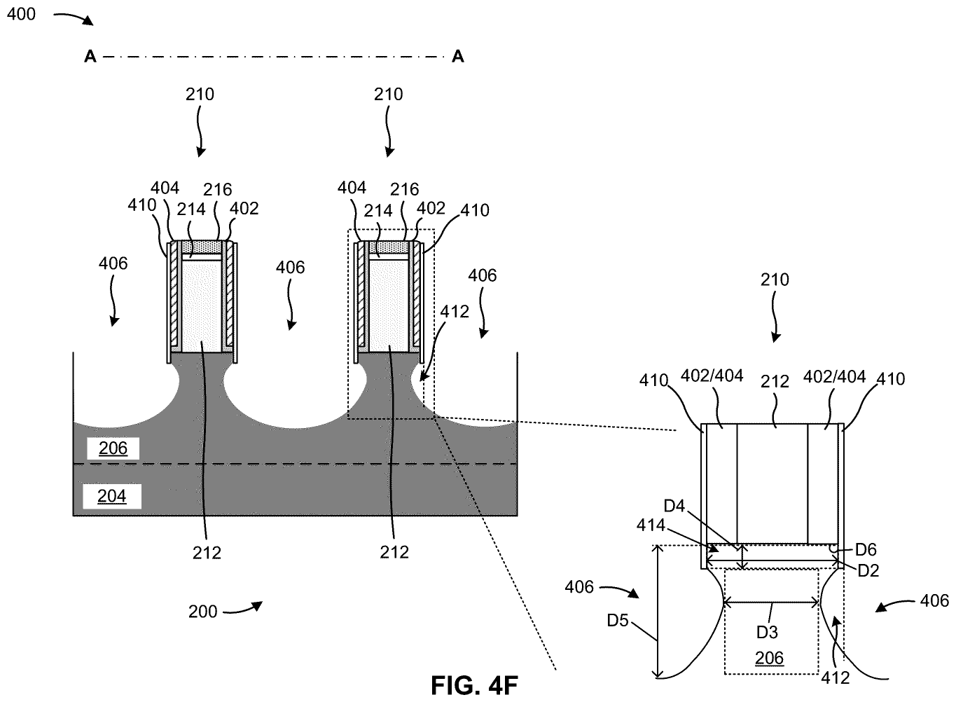

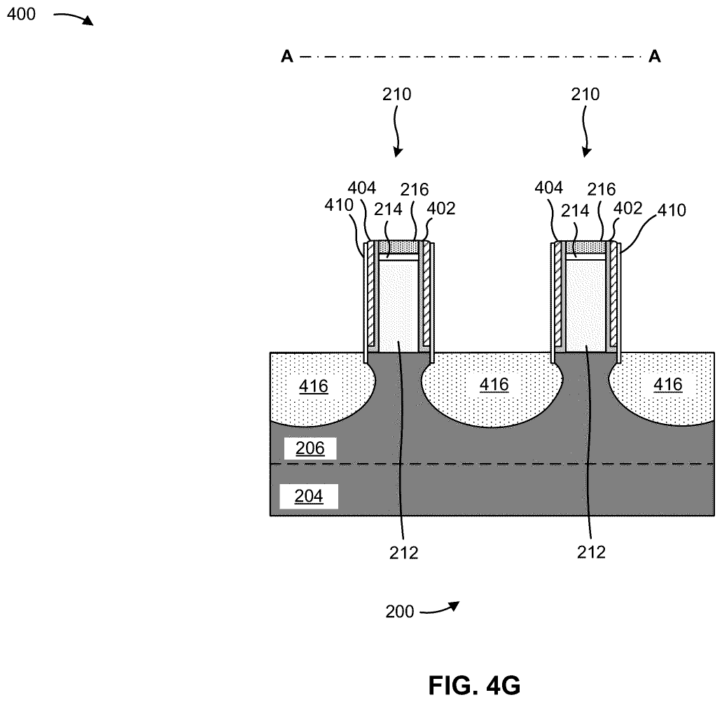

FIGS. 4A-4G are diagrams of an example implementation 400 described herein. The example implementation 400 includes an example of forming source/drain regions in the source/drain areas 218 of the device region 202 of the semiconductor device 200. FIGS. 4A-4G are illustrated from the perspective of the cross-sectional plane A-A in FIG. 2 for the device region 202. In some implementations, the operations described in connection with the example implementation 400 are performed after the fin formation process described in connection with FIGS. 3A-3D.

As shown in FIG. 4A, dummy gate structures 210 are formed in the device region 202. The dummy gate structures 210 are formed and included over the fin structures 206, and around the sides of the fin structures 206 such that the dummy gate structures 210 surround the fin structure 206 on at least three sides of the fin structure 206. The dummy gate structures 210 are formed as placeholders for the actual gate structures (e.g., replacement high-k gate structures or metal gate structures) that are to be formed for the transistors included in the device region 202. The dummy gate structures 210 may be formed as part of a replacement gate process, which enables other layers and/or structures to be formed prior to formation of the replacement gate structures.

The dummy gate structures 210 include the gate electrode layers 212, the hard mask layers 214, and/or the capping layers 216, among other examples. The gate electrode layers 212 may each include a polysilicon layer or other suitable layers. For example, the gate electrode layers 212 may be formed (e.g., using a deposition tool 102) by suitable deposition processes such as LPCVD or PECVD, among other examples. The hard mask layers 214 may each include any material suitable to pattern the gate electrode layers 212 with particular dimensions and/or attributes. Examples include silicon nitride (SiₓN_{y} such as Si₃N₄), silicon oxynitride (SiON), silicon carbon nitride (SiCN), or a combination thereof, among other examples. The hard mask layers 214 may be deposited (e.g., using a deposition tool 102) by CVD, PVD, ALD, or another suitable deposition process. The capping layers 216 may each include dielectric oxide layers. As an example, the capping layers 216 may each be formed (e.g., using a deposition tool 102) by chemical oxidation, thermal oxidation, ALD, CVD, and/or other suitable deposition processes.

As further shown in FIG. 4A, seal spacer layers 402 are included on the sidewalls of the dummy gate structures 210. The seal spacer layers 402 may be conformally deposited (e.g., using a deposition tool 102) and may include a silicon oxycarbide (SiOC), a nitrogen free SiOC, or another suitable material. The seal spacer layers 402 may be formed by an ALD operation in which various types of precursor gasses including silicon (Si) and carbon are sequentially supplied in a plurality of alternating cycles to form the seal spacer layers 402, among other example deposition techniques.

As further shown in FIG. 4A, bulk spacer layers 404 may be formed on the seal spacer layers 402. The bulk spacer layers 404 may be formed of similar materials as the seal spacer layers 402. However, the bulk spacer layers 404 may formed without plasma surface treatment that is used for the seal spacer layers 402. Moreover, the bulk spacer layers 404 may be formed to a greater thickness relative to the thickness of the seal spacer layers 402.

In some implementations, the seal spacer layers 402 and the bulk spacer layers 404 are conformally deposited (e.g., using a deposition tool 102) on the dummy gate structures 210, and on the fin structures 206. The seal spacer layers 402 and the bulk spacer layers 404 are then patterned (e.g., using a deposition tool 102, an exposure tool 104, and a developer tool 106) and etched (e.g., using an etch tool 108) to remove the seal spacer layers 402 and the bulk spacer layers 404 from the tops of the dummy gate structures 210 and from the fin structures 206.

As shown in FIGS. 4B-4E, source/drain recesses 406 are formed in the fin structures 206 in the device region 202 adjacent to and/or between the dummy gate structures 210 in a plurality of etch operations. The plurality of etch operations may be referred to a strained source/drain (SSD) etch process, and the source/drain recesses 406 may be referred to as strained source/drain recesses.

As shown in FIG. 4B, a first etch operation is performed to form the source/drain recesses 406 to a first depth. The first etch operation includes an anisotropic etch, which may be performed using a dry etch technique such as dry plasma-based etching. The use of the dry etch technique enables a highly directional (e.g., vertical) etching of the fin structure 206 to be performed using an etch tool 108, which enables the source/drain recesses 406 to be formed such that the sidewalls of the source/drain recesses 406 are vertical or have minimal rounding or taper.

As shown in FIG. 4C, a protection layer 408 is formed on the semiconductor device 200 after the first etch operation. The protection layer 408 is used to form sidewall protection layers on the dummy gate structures 210. The sidewall protection layers are used to precisely control the shape or profile of the source/drain recesses 406 in subsequent etch operations.

The protection layer 408 may be conformally deposited in the source/drain recesses 406, on the sidewalls of the dummy gate structures 210 (e.g., on the seal spacer layers 402 and/or on the bulk spacer layers 404 that are on the sidewalls of the dummy gate structures 210), and/or on the top surfaces of the dummy gate structures (e.g., on the capping layer 216 of the dummy gate structures 210). A deposition tool 102 may be used to deposit the protection layer 408 in a PVD operation, an ALD operation, a CVD operation, an oxidation operation, another type of deposition operation described in connection with FIG. 1, and/or another suitable deposition operation.

The protection layer 408 may be formed to a thickness (dimension D1 in FIG. 4C) that is included in a range of approximately 0.1 nanometers to approximately 15 nanometers. Forming the protection layer 408 to a thickness of less than approximately 0.1 nanometers may result in voids, gaps, and/or other discontinuities in the protection layer 408, which may result in an inability of the sidewall protection layers that are formed from the protection layer 408 to effectively protect portions of the fin structure 206 under the dummy gate structures 210 from being etched. Forming the protection layer 408 to a thickness greater than approximately 15 nanometers may result in reduced width between the dummy gate structures 210, which may result in less area between the dummy gate structures 210 for source/drain interconnects. This may result in reduced gap-filling performance for the source/drain interconnects and/or increased resistance for the source/drain interconnects, among other examples. Forming the protection layer 408 to a thickness that is included in the range of approximately 0.1 nanometers to approximately 15 nanometers enables the effectively protect portions of the fin structure 206 under the dummy gate structures 210 from being etched while minimizing reduction in gap-filling performance for the source/drain interconnects and enabling a sufficiently low resistance to be achieved for the source/drain interconnects. However, other values for the thickness of the protection layer 408, and ranges other than approximately 0.1 nanometers to approximately 15 nanometers, are within the scope of the present disclosure.

The protection layer 408 may include one or more materials that provide etch selectivity relative to the material of the fin structure 206. For example, the protection layer 408 may include a polymer material, a dielectric material, and/or another material that provides etch selectivity relative to the semiconductor material(s) (e.g., silicon (Si), germanium (Ge), silicon germanium (SiGe)) of the fin structure 206. This enables the sidewall protection layers that are formed from the protection layer 408 to precisely control etching of the fin structure 206 in a subsequent etch operation to control the formation of the profile of the source/drain recesses 406. The material(s) of the protection layer 408 may be deposited by in-situ and/or ex-situ deposition. Examples of polymer materials for the protection layer 408 include polybenzoxazole (PBO), a polyimide, a low temperature polyimide (LTPI), an epoxy resin, an acrylic reason, a phenol resin, and/or benzocyclobutene (BCB), among other examples. Examples of dielectric materials for the protection layer 408 include a silicon oxide (SiOₓ such as SiO₂), a silicon nitride (SiₓN_{y} such as Si₃N₄), silicon oxycarbonitride (SiOCN), silicon oxynitride (SiON), and/or silicon carbon nitride (SiCN), among other examples.

As shown in FIG. 4D, a second etch operation is performed, after formation of the protection layer 408, to increase the depth of the source/drain recesses 406 from the first depth to a second depth that is greater than the first depth. The second etch operation includes another anisotropic etch, which may be performed using a dry etch technique such as dry plasma-based etching. The use of the dry etch technique enables a highly directional (e.g., vertical) etching of the fin structure 206 to be performed using an etch tool 108, which enables the source/drain recesses 406 to be formed such that the sidewalls of the source/drain recesses 406 are vertical or have minimal rounding or taper.

As further shown in FIG. 4D, portions of the protection layer 408 are removed during the second etch operation, resulting in formation of sidewall protection layers 410 on the sides of the dummy gate structures 210. In particular, the sidewall protection layers 410 correspond to remaining portions of the protection layer 408 that remain on the bulk spacer layers 404 that are on the sidewalls of the dummy gate structures 210. The portions of the protection layer 408 on the bottom surfaces of the source/drain recesses 406 are removed. The portions of the protection layer 408 on the top surfaces of the dummy gate structures 210 (e.g., on the capping layers 216 of the dummy gate structures 210) are also removed. However, other portions of the protection layer 408 (corresponding to portions of the sidewall protection layers 410) remain on sidewalls of the source/drain recesses 406 because of the highly directional etch that is performed for the second etch operation. Thus, bottom portions of the sidewall protection layers 410 extend and/or located below the top surface of the fin structure 206 under the dummy gate structures 210, and below the bottom surface of the dummy gate structures 210.

As shown in FIG. 4E, a third etch operation is performed, after the second etch operation, to define or reduce the channel length between source/drain regions under the dummy gate structures 210. The third etch operation also results in the depth of the source/drain recesses 406 being increased from the second depth to a third depth that is greater than the second depth. The third etch operation includes an isotropic etch, which may be performed using a wet etch technique involving a wet etchant (e.g., a chemical etchant). The use of the wet etch technique enables an omnidirectional etching of the fin structure 206 to be performed using an etch tool 108, which enables the source/drain recesses 406 to be laterally etched. Lateral etching of the source/drain recesses 406 enables the source/drain recesses 406 to be expanded under a dummy gate structures 210, thereby enabling the channel length (e.g., the distance between source/drain recesses 406 on opposing sides of the dummy gate structure 210) to be reduced.

To achieve the lateral etching of the fin structures 206 in the source/drain recesses 406, an anisotropic wet etchant may be used in the etch tool 108. The anisotropic wet etchant may include, for example, a combination of nitric acid (HNO₃) and hydrofluoric acid (HF), among other examples. The nitric acid may be used to oxidize the silicon of the fin structure 206 in the source/drain recesses 406, and the hydrofluoric acid may be used to isotropically etch the oxidized silicon. However, other isotropic wet etchants may be used to isotropically etch the fin structures 206 through the source/drain recesses 406.

As further shown in FIG. 4E, the lateral etching of the fin structures 206 through the source/drain recesses 406 results in extension regions 412 of the source/drain recesses 406. The extension regions 412 are regions of the source/drain recesses 406 that extend under the bottom surfaces of the dummy gate structures 210. The formation of the extension regions 412 enables the width and shape of the fin structure 206 under the dummy gate structures 210 to be precisely formed or controlled.

As shown in FIG. 4F, the sidewall protection layers 410 on the sidewalls of the dummy gate structures 210 protect the dummy gate structures 210 from etching during the third etching operation, and also enable further precision in controlling the final widths and profiles of the fin structure 206 under the dummy gate structures 210. In particular, the portions of the sidewall protection layers 410 that extend below the bottom surfaces of the dummy gate structures 210 and into the source/drain recesses 406 provide buffer regions 414 in the fin structure 206 under the dummy gate structures 210. The buffer regions 414 are protected from lateral etching, which preserves the full widths of the fin structure 206 under the dummy gate structures 210 after the second etch operation. This enables the channel length under the dummy gate structures 210 to be reduced during the third etch operation in a way that results in the curvature of the sidewalls of the source/drain recesses 406 being located further down on the fin structure 206 under the dummy gate structures 210 than without the sidewall protection layers 410. This reduces the likelihood of metal gate extrusion (e.g., the physical contact of a source/drain recess with a metal gate structure) after the dummy gate structures 210 are replaced with metal gate structures. As described above, residual dummy gate material may remain after the dummy gate structures 210 are removed. Regions of the residual dummy gate material may be wider at the top of the fin structure 206 near the bottom surface of the dummy gate structures 210, and may reduce in width further down toward the bottom of the fin structure 206. The sidewall protection layers 410 prevent or minimize the reduction in width of the fin structure in the buffer regions 414 directly under the dummy gate structures 210, which minimizes or prevents the likelihood of the source/drain recesses 406 being expanded into the regions of the residual dummy gate material. This reduces the likelihood of contact (and electrical shorting) between the metal gate structure and source/drain regions that are formed in the source/drain recesses 406.

As further shown in FIG. 4F, the semiconductor device 200 may include one or more dimensions, such as a dimension D2, a dimension D3, a dimension D4, a dimension D5, and/or a dimension D6, among other examples. The dimension D2 corresponds to a width of a buffer region 414 of the fin structure 206 under a dummy gate structure 210. The dimension D3 corresponds to the shortest channel length in the fin structure 206 under the dummy gate structure 210. The dimension D3 is less than the dimension D2 as a result of the lateral etching of the source/drain recesses 406 in the third etch operation, and as a result of the sidewall protection layers 410 protecting the buffer region 414 during the third etch operation. The dimension D4 corresponds to a thickness of the buffer region 414 of the fin structure 206 under the dummy gate structure 210.

The dimension D4 also corresponds to the distance that the sidewall protection layers 410 extend under the bottom surface of the dummy gate structure 210. In some implementations, the dimension D4 is included in a range of greater than 0% of the total depth of the source/drain recesses 406 (which corresponds to the dimension D6 in FIG. 4F), to approximately 50% of the total depth of the source/drain recesses 406. If the dimension D4 is 0%, the sidewall protection layers 410 do not extend below the dummy gate structure 210 and do not provide protection for etching of the buffer region 414, which may result in the source/drain regions that are formed in the source/drain recesses 406 being in contact with residual dummy gate material. If the dimension D4 is greater than approximately 50%, the location of the shortest channel length through the fin structure 206 under the dummy gate structure 210 may be too low in the fin structure 206, and the metal gate structure that replaces the dummy gate structure 210 may not be able to control the conductivity of the channel in the fin structure 206. If the dimension D4 is in the range of greater than 0% to approximately 50%, the metal gate structure may be able to sufficiently control the conductivity of the channel in the fin structure 206, and the likelihood of the source/drain regions that are formed in the source/drain recesses 406 being in contact with residual dummy gate material is reduced. However, other values for the dimension D4, and ranges other than greater than 0% to approximately 50%, are within the scope of the present disclosure.

In some implementations, the dimension D5 is included in a range of greater than approximately 0 nanometers to approximately 100 nanometers, depending on the type of transistor being formed (e.g., a high-voltage transistor, a low-voltage transistor), a use case for the transistor (e.g., logic, power supply, memory, photodiode), and/or one or more parameters for the transistor, among other examples. However, other values for the range are within the scope of the present disclosure. The dimension D6 corresponds to an angle between the top surface of the fin structure 206 and a sidewall of the buffer region 414 of the fin structure 206. In some implementations, the dimension D6 is included in a range of approximately 80 degrees to approximately 100 degrees. However, other values for the range are within the scope of the present disclosure.

As shown in FIG. 4G, source/drain regions 416 are formed in the source/drain recesses 406 in the device region 202 of the semiconductor device 200 over the substrate 204. A deposition tool 102 is used to form the source/drain regions 416 using an epitaxy technique, in which layers of the epitaxial material are deposited in the source/drain recesses 406 such that the layers of p-type source/drain regions and/or layers of n-type source/drain regions are formed by epitaxial growth in a particular crystalline orientation. The source/drain regions 416 are included between the dummy gate structures 210 and at least partially below and/or lower than the dummy gate structures 210. Moreover, the source/drain regions 416 at least partially extend above the top surface of the fin structures 206.

The material (e.g., silicon (Si), gallium (Ga), or another type of semiconductor material) that is used to form the source/drain regions 416 may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation. Examples of p-type dopants that may be used in the epitaxial operation include boron (B) or germanium (Ge), among other examples. The resulting material of p-type source/drain regions include silicon germanium (SixGe₁₋ₓ, where x can be in a range from approximately 0 to approximately 100) or another type of p-doped semiconductor material. Examples of n-type dopants that may be used in the epitaxial operation include phosphorous (P) or arsenic (As), among other examples. The resulting material of n-type source/drain regions include silicon phosphide (SiₓP_{y}) or another type of n-doped semiconductor material.

As indicated above, FIGS. 4A-4G are provided as an example. Other examples may differ from what is described with regard to FIGS. 4A-4G.

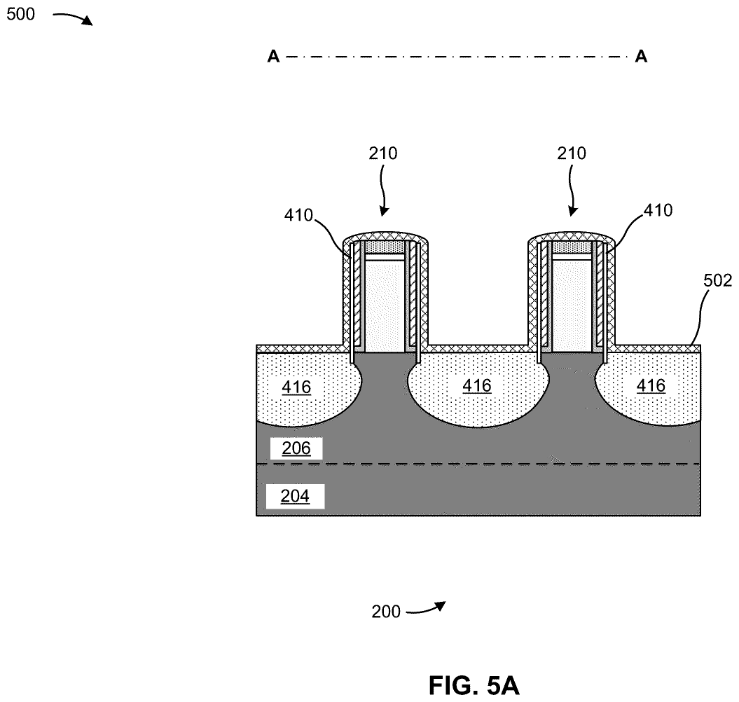

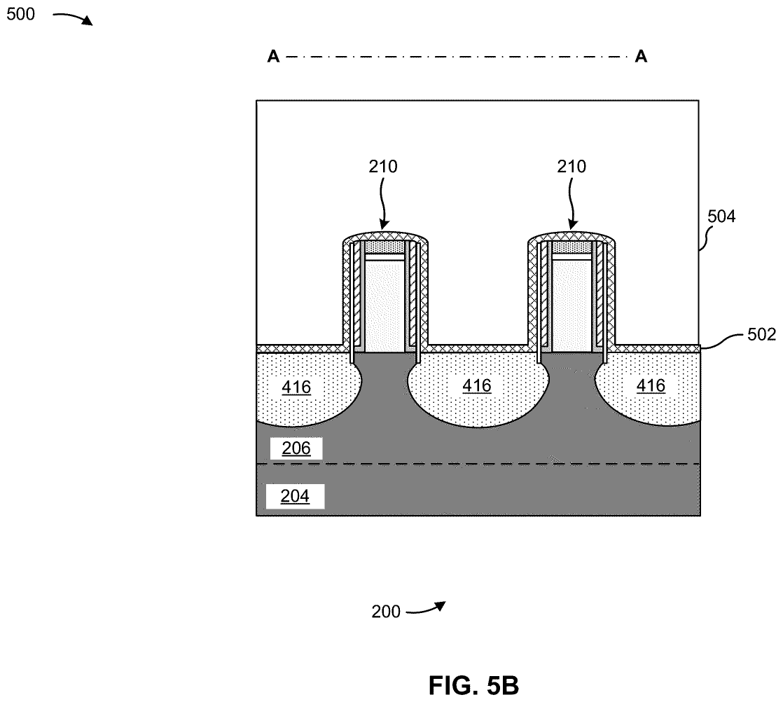

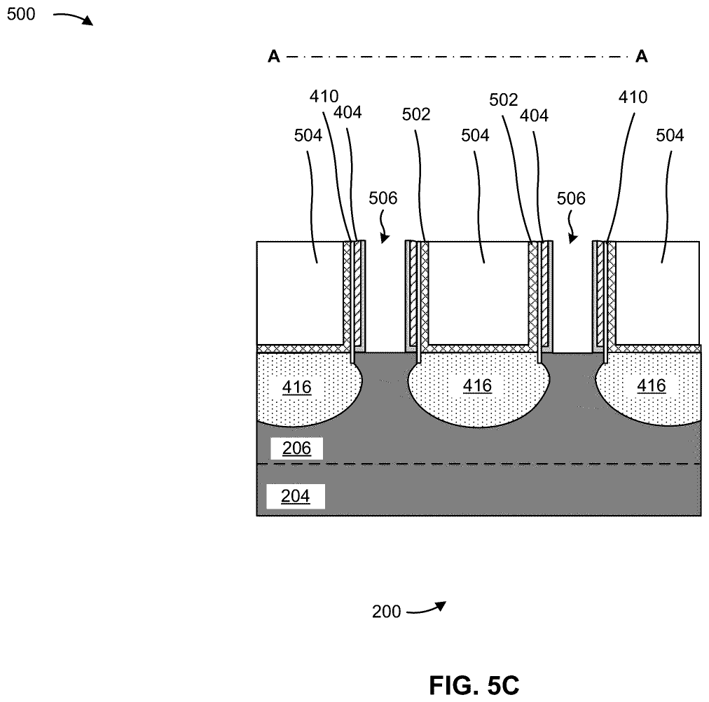

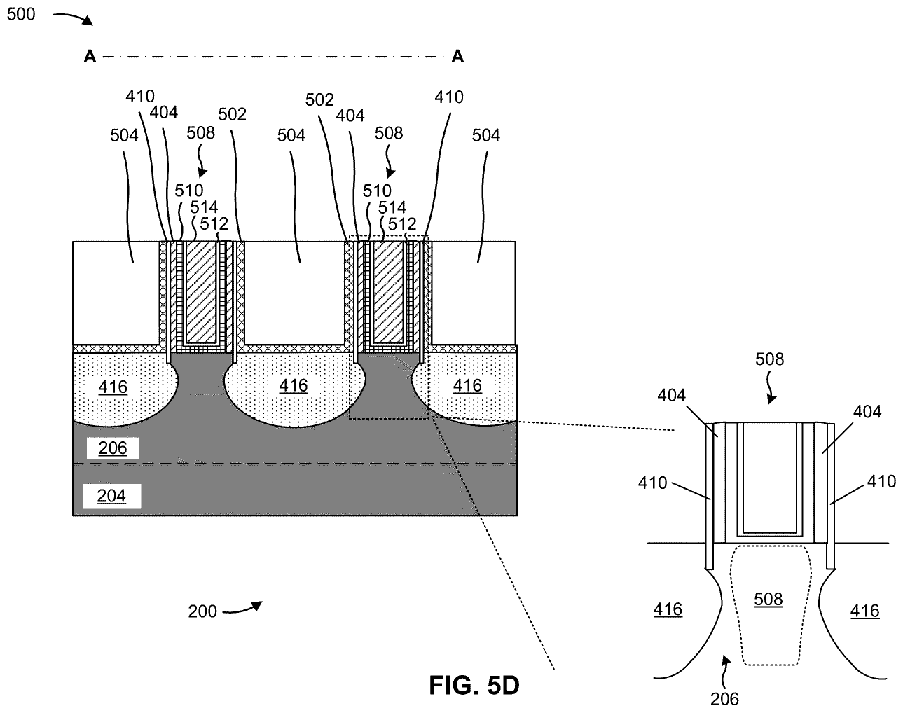

FIGS. 5A-5D are diagrams of an example implementation 500 described herein. The example implementation 500 includes an example dummy gate replacement process, in which the dummy gate structures 210 are replaced with high-k gate structures and/or metal gate structures. FIGS. 5A-5D are illustrated from the perspective of the cross-sectional plane A-A in FIG. 2 for the device region 202.

As shown in FIG. 5A, a contact etch stop layer (CESL) 502 is conformally deposited (e.g., using a deposition tool 102) over the source/drain regions 416, over the dummy gate structures 210, and on the sidewall protection layers 410. The CESL 502 may provide a mechanism to stop an etch process when forming contacts or vias for the device region 202. The CESL 502 may be formed of a dielectric material having a different etch selectivity from adjacent layers or components. The CESL 502 may include or may be a nitrogen containing material, a silicon containing material, and/or a carbon containing material. Furthermore, the CESLs 502a and 502b may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 502 may be deposited using a deposition process, such as ALD, CVD, or another deposition technique.

As shown in FIG. 5B, an interlayer dielectric (ILD) layer 504 is formed (e.g., using a deposition tool 102) over and/or on the CESL 502. The ILD layer 504 fills in the areas between the dummy gate structures 210 over the source/drain regions 416. The ILD layer 504 is formed to permit a replacement gate structure process to be performed in the device region 202, in which metal gate structures are formed to replace the dummy gate structures 210. The ILD layer 504 may be referred to as an ILD zero (ILD0) layer.

In some implementations, the ILD layer 504 is formed to a height (or thickness) such that the ILD layer 504 covers the dummy gate structures 210. In these implementations, a subsequent CMP operation (e.g., performed using a planarization tool 110) is performed to planarize the ILD layer 504 such that the top surfaces of the ILD layer 504 are approximately at a same height as the top surfaces of the dummy gate structures 210. This increases the uniformity of the ILD layer 504.

As shown in FIG. 5C, the replacement gate operation is performed (e.g., by one or more of the semiconductor processing tools 102-112) to remove the dummy gate structures 210 from the device region 202. The removal of the dummy gate structures 210 leaves behind openings (or recesses) 506 between the bulk spacer layers 404 and between the source/drain regions 416. The dummy gate structures 210 may be removed in one or more etch operations includes a plasma etch technique, which may include a wet chemical etch technique, and/or another type of etch technique.

As shown in FIG. 5D, the replacement gate operation continues where deposition tool 102 and/or the plating tool 112 forms the gate structures (e.g., replacement gate structures) 508 in the openings 506 between the bulk spacer layers 404 and between the source/drain regions 416. The gate structures 508 may include metal gate structures, high-k gate structures, or other types of gate structures. The gate structures 508 may include an interfacial layer (not shown), a high-k dielectric layer 510, a work function tuning layer 512, and a metal electrode structure 514 formed therein to form a gate structure 508. In some implementations, the gate structures 508 may include other compositions of materials and/or layers.

As shown in a close-up view in FIG. 5D, the semiconductor device 200 includes a fin structure 206, a gate structure 508 wrapping around at least three sides of the fin structure 206, source/drain regions 416 on the fin structure 206 and adjacent to opposing sides of the gate structure 508, bulk spacer layers 404 on opposing sides of the gate structure 508, and sidewall protection layers 410 on the bulk spacer layers 404. The sidewall protection layer 410 are retained in the semiconductor device 200 after formation of the source/drain regions 416 and extend below a bottom surface of the gate structure 508. Thus, the portions of the sidewall protection layers 410 that is below the bottom surface of the gate structure 508 is located between portions of the source/drain region 416 and portions of the fin structure 206 that are under the gate structure 508. The sidewall protection layers 410 on the sides of the gate structure 508 enables the source/drain regions 416 on opposing sides of the gate structure 508 to be formed such that the source/drain regions 416 do not contact the portions of the gate structure 508 (shown in dashed lines in the close-up view in FIG. 5D) that were formed in place of residual dummy gate material from the dummy gate structures 210. Thus, the sidewall protection layers 410 reduce the likelihood of extrusion of the gate structure 508 into the source/drain regions 416, which reduces the likelihood of electrical shorting between the gate structure 508 and the source/drain regions 416.

As indicated above, FIGS. 5A-5D are provided as an example. Other examples may differ from what is described with regard to FIGS. 5A-5D.

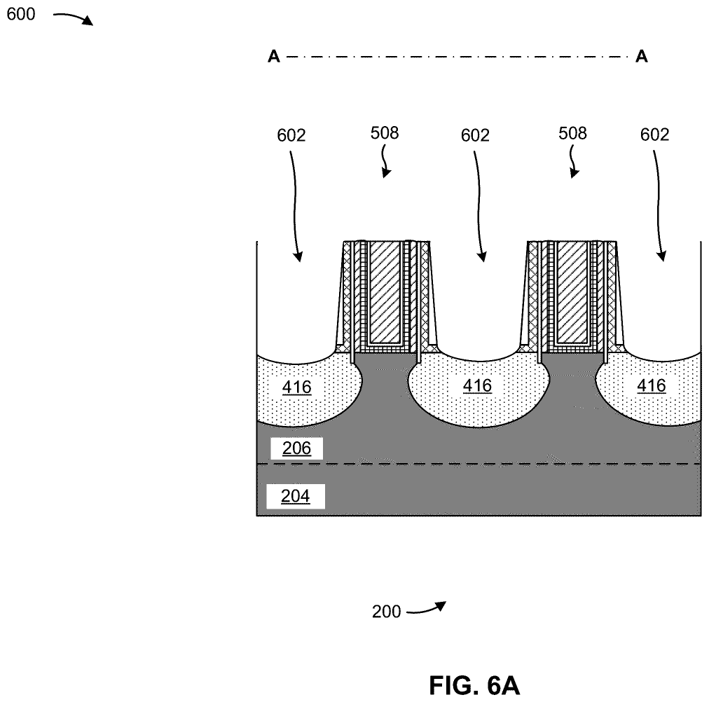

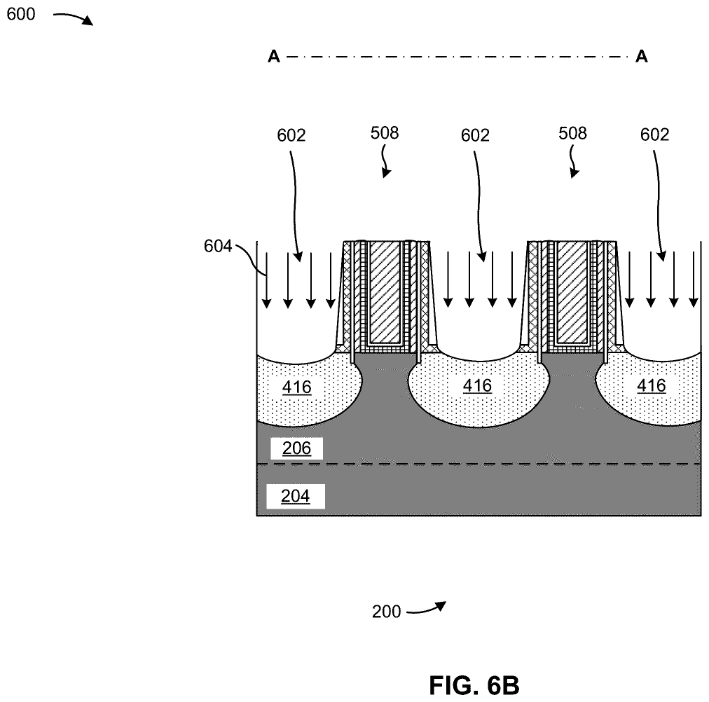

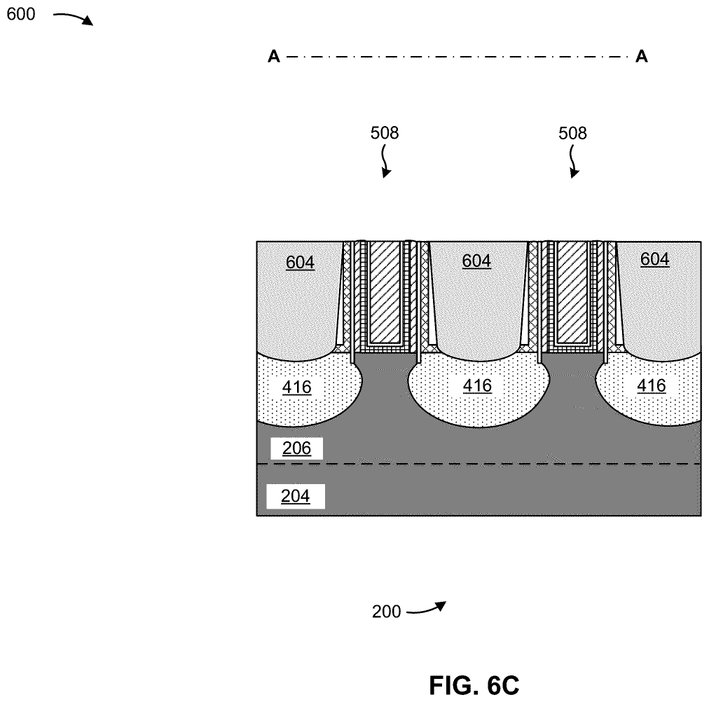

FIGS. 6A-6C are diagrams of an example implementation 600 described herein. The example implementation 600 includes an example of forming conductive structures (e.g., metal gate contacts or MDs) in the device region 202 of the semiconductor device 200. FIGS. 6A-6C are illustrated from the perspective of the cross-sectional plane A-A in FIG. 2 for the device region 202.

As shown in FIG. 6A, openings (or recesses) 602 are formed through one or more dielectric layers and to the source/drain regions 416. In particular, the CESL 502 and the ILD layer 504 between the gate structures 508 in the device region 202 are etched to form the openings 602 between the gate structures 508 and to the source/drain regions 416. In some implementations, the openings 602 are formed in a portion of the source/drain regions 416 such that recesses extend into a portion of the source/drain regions 416. An opening 602 includes a bottom surface corresponding to a top surface of an associated source/drain region 416, and a plurality of sidewalls corresponding to sides of the CESL 502 and/or the ILD layer 504.

In some implementations, a pattern in a photoresist layer is used to form the openings 602. In these implementations, the deposition tool 102 forms the photoresist layer on the ILD layer 504, and on the gate structures 508. The exposure tool 104 exposes the photoresist layer to a radiation source to pattern the photoresist layer. The developer tool 106 develops and removes portions of the photoresist layer to expose the pattern. The etch tool 108 etches into the ILD layer 504 to form the openings 602. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the openings 602 based on a pattern.

As shown in FIG. 6B, a pre-clean operation is performed to clean the surfaces in the openings 602. In particular, the semiconductor device 200 may be positioned in a first processing chamber of the deposition tool 102 (e.g., a pre-clean processing chamber), the first processing chamber may be pumped down to an at least partial vacuum (e.g., pressurized to a pressure that is included in a range of approximately 5 Torr to approximately 10 Torr, or to another pressure), and the bottom surfaces and the sidewalls in the openings 602 are cleaned using a plasma-based and/or a chemical-based pre-clean agent. The pre-clean operation is performed to clean (e.g., remove) oxides and other contaminants or byproducts from the top surfaces source/drain regions 416 that may have formed after the formation of the openings 602.

As shown in FIG. 6C, conductive structures 604 are formed in the device region 202. In particular, conductive structures 604 are formed in the openings 602 between the gate structures 508 and over the source/drain regions 416 in the openings 602. The deposition tool 102 and/or the plating tool 112 deposits the conductive structures 604 by a CVD technique, a PVD technique, an ALD technique, an electroplating technique, another deposition technique described above in connection with FIG. 1, and/or a deposition technique other than as described above in connection with FIG. 1. In some implementations, one or more additional layers are formed in the openings 602 prior to formation of the conductive structures 604. As an example, a metal silicide layer (e.g., titanium nitride (TiSiₓ) or another metal silicide layer) may be formed on the top surfaces of the source/drain regions 416 prior to formation of the conductive structures 604. As another example, one or more barrier layers may be formed on the bottom surfaces and/or on the sidewalls in the openings 602 prior to formation of the conductive structures 604. As another example, one or more adhesion layers may be formed on the bottom surfaces and/or on the sidewalls in the openings 602 prior to formation of the conductive structures 604.

As indicated above, FIGS. 6A-6C are provided as an example. Other examples may differ from what is described with regard to FIGS. 6A-6C.

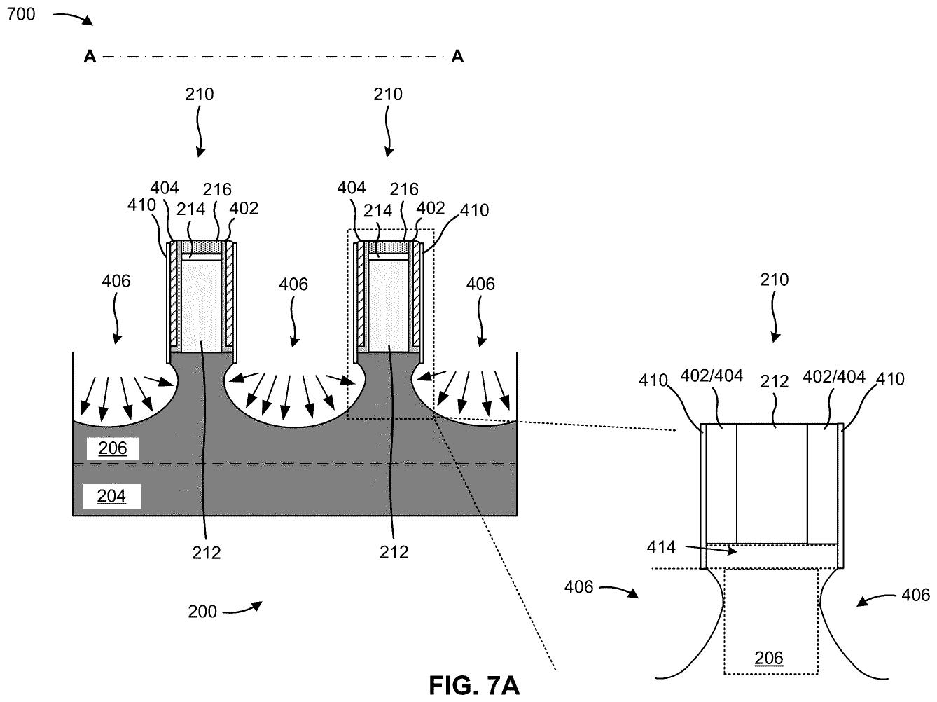

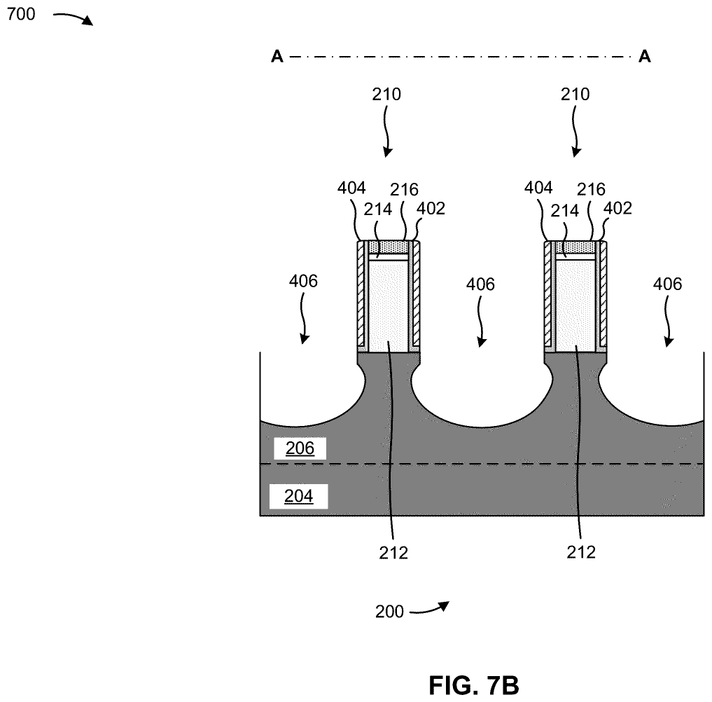

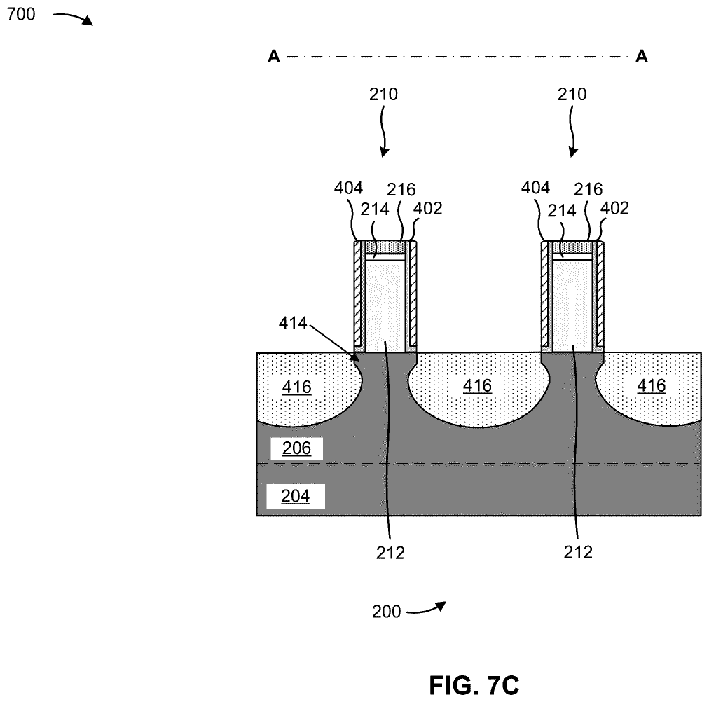

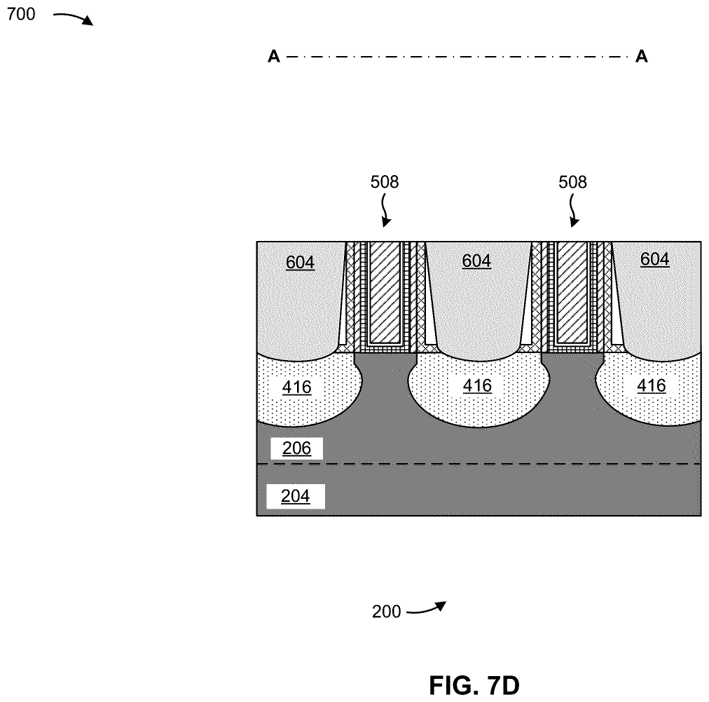

FIGS. 7A-7D are diagrams of an example implementation 700 described herein. The example implementation 700 includes an alternative implementation, to the implementations of FIGS. 4A-4G, 5A-5D, and 6A-6C, of forming the semiconductor device 200. In particular, the example implementation 700 is similar to the example implementations 400, 500, and 600, except that the sidewall protection layers 410 are removed from the semiconductor device 200 in the example implementation 700 after formation of the source/drain recesses 406. Removal of the sidewall protection layers 410 provides a greater area between the dummy gate structures 210 for forming source/drain interconnects (e.g., the conductive structures 604). This provides improved gap-filling performance for the source/drain interconnects and/or reduced resistance for the source/drain interconnects, among other examples. However, retaining the sidewall protection layers 410 in the semiconductor device 200, as in the example implementations 400, 500, and 600, results in fewer semiconductor processing operations for the semiconductor device 200, and therefore reduced manufacturing time, cost, and resource consumption.

FIGS. 7A-7D are illustrated from the perspective of the cross-sectional plane A-A in FIG. 2 for the device region 202. Turning to FIG. 7A, the operations described in connection with the example implementation 700 are performed after the fin formation process described in connection with FIGS. 3A-3D, and after the dummy gate formation operations and the source/drain recess etching operations described in connection with FIGS. 4A-4G.

As shown in FIG. 7B, after the third etch operation for laterally etching the source/drain recesses 406 while the sidewall protection layers 410 facilitate controlled shaping of the source/drain recesses 406, the sidewall protection layers 410 are removed from the sides of the dummy gate structures 210 in the example implementation 700. The portions of the sidewall protection layers 410 that extend along the fin structures 206 and below the dummy gate structures 210 are also removed. The sidewall protection layers 410 are removed prior to formation of the source/drain regions 416 in the source/drain recesses 406. An etch tool 108 may be used to selectively remove the sidewall protection layers 410. A dry etch operation, a wet etch operation, a combination thereof, and/or another type of etch operation may be performed to remove the sidewall protection layers 410.

As shown in FIG. 7C, the source/drain regions 416 may be formed in the source/drain recesses 406 after the sidewall protection layers 410 are removed. Thus, the source/drain regions 416 are in direct contact with the buffer regions 414 of the fin structure 206 under the dummy gate structures 210.

As shown in FIG. 7D, additional semiconductor processing operations described in connection with FIGS. 5A-5D and/or 6A-6C may be performed to replace the dummy gate structures 210 with the gate structures 508, and to form the conductive structures 604.

As indicated above, FIGS. 7A-7D are provided as an example. Other examples may differ from what is described with regard to FIGS. 7A-7D.

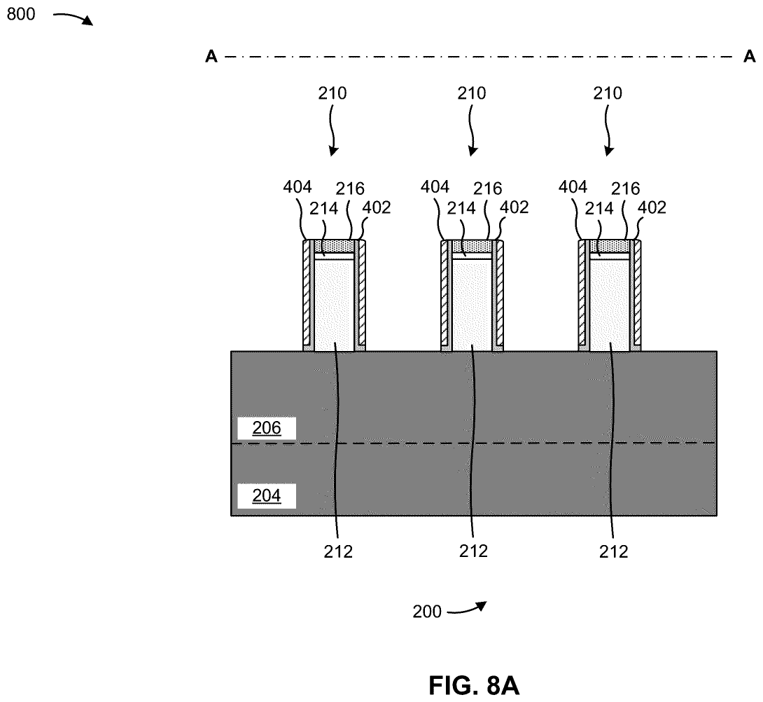

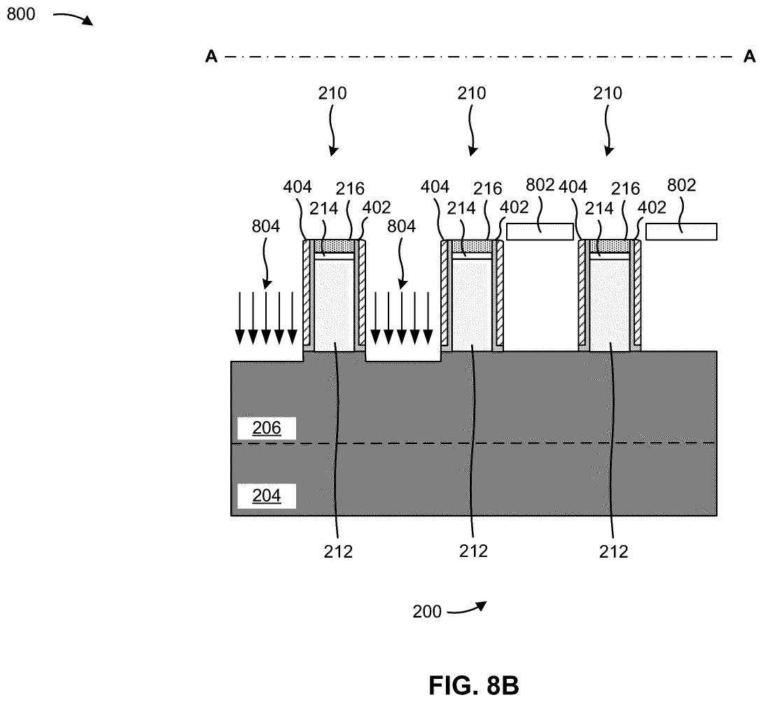

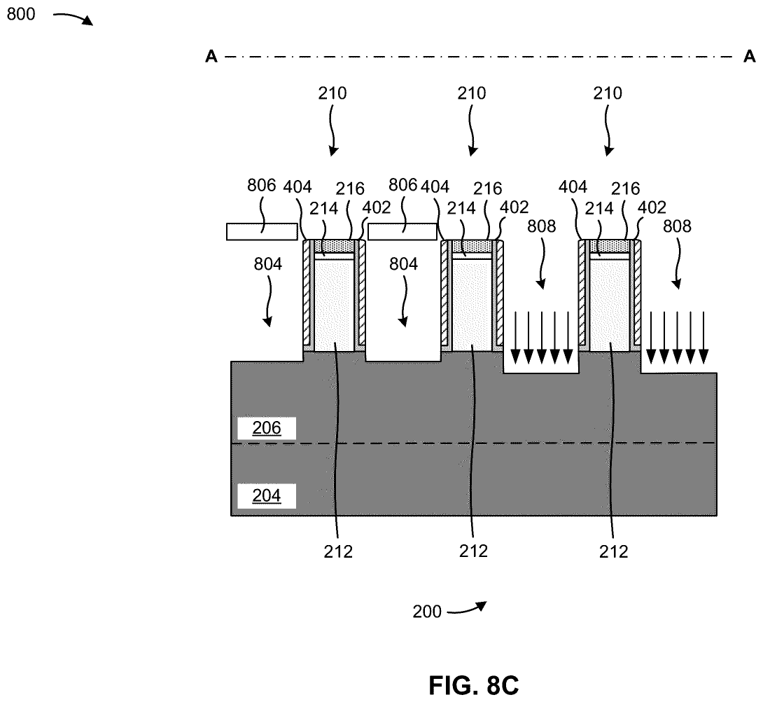

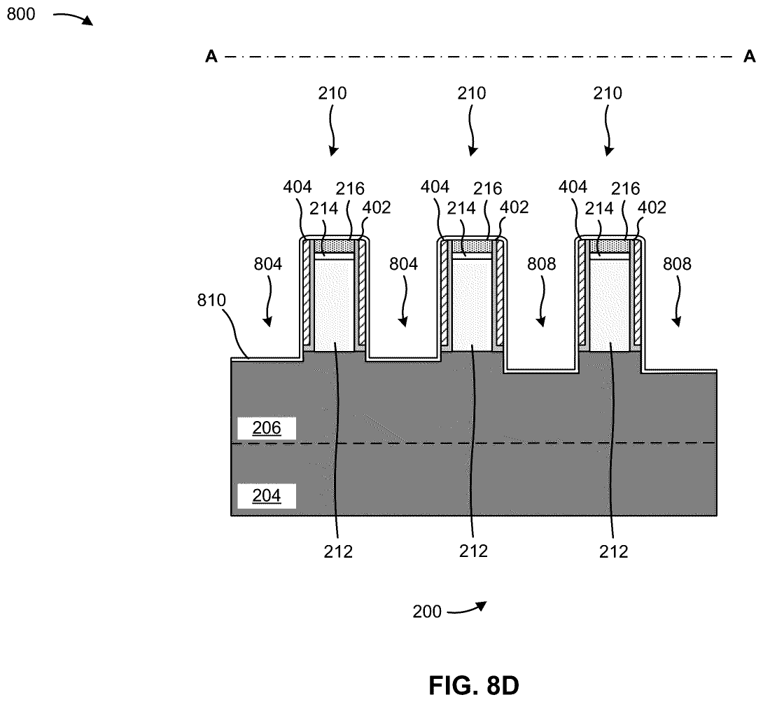

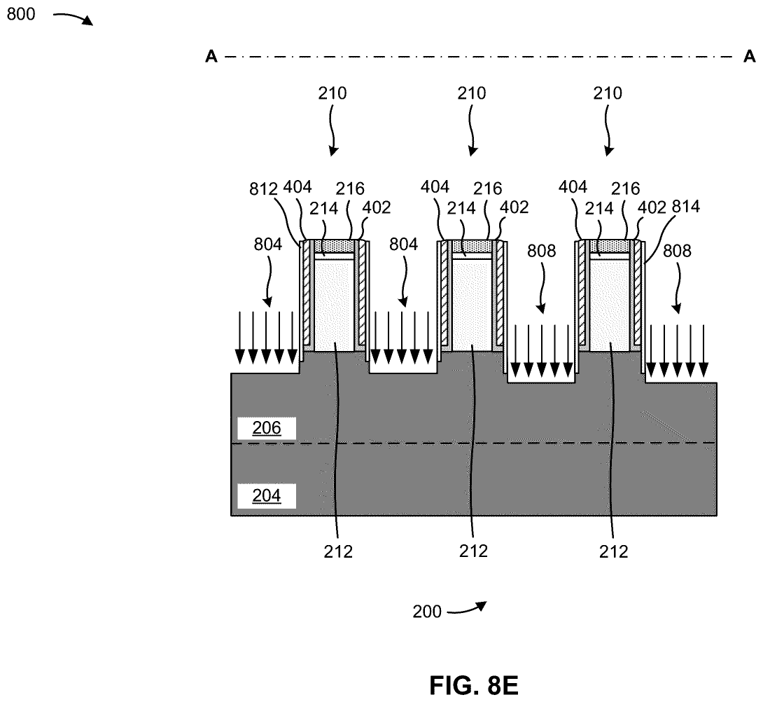

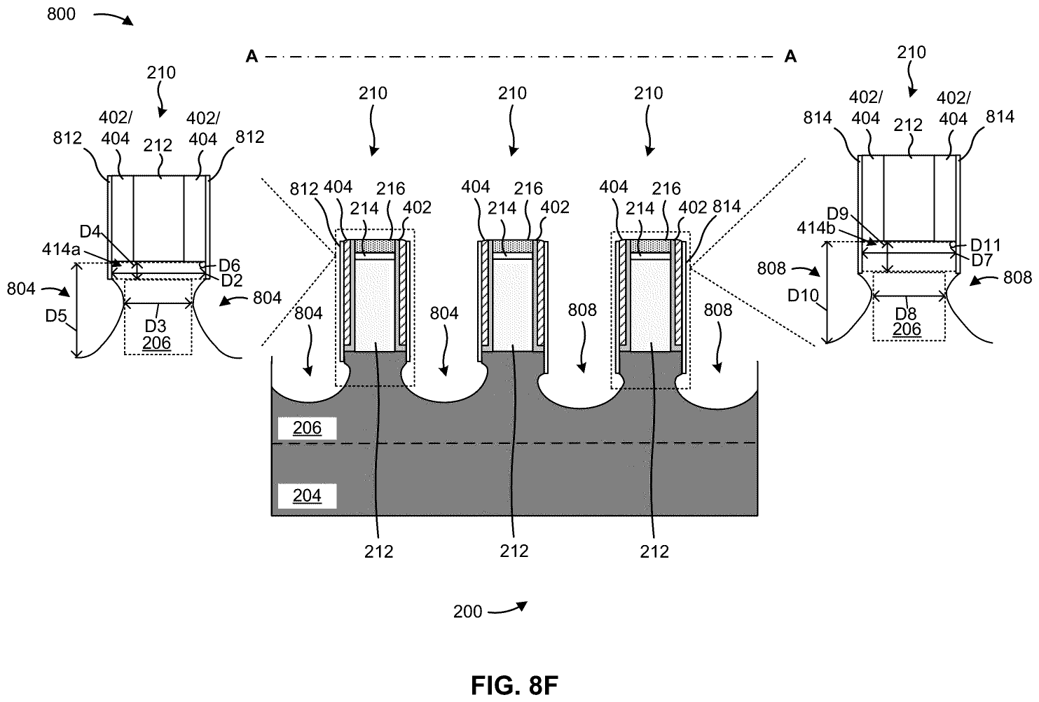

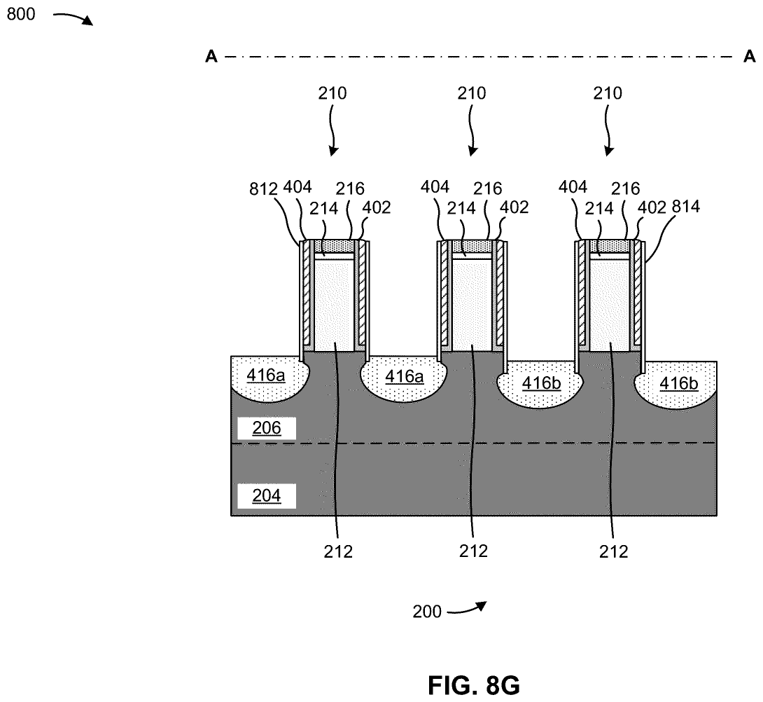

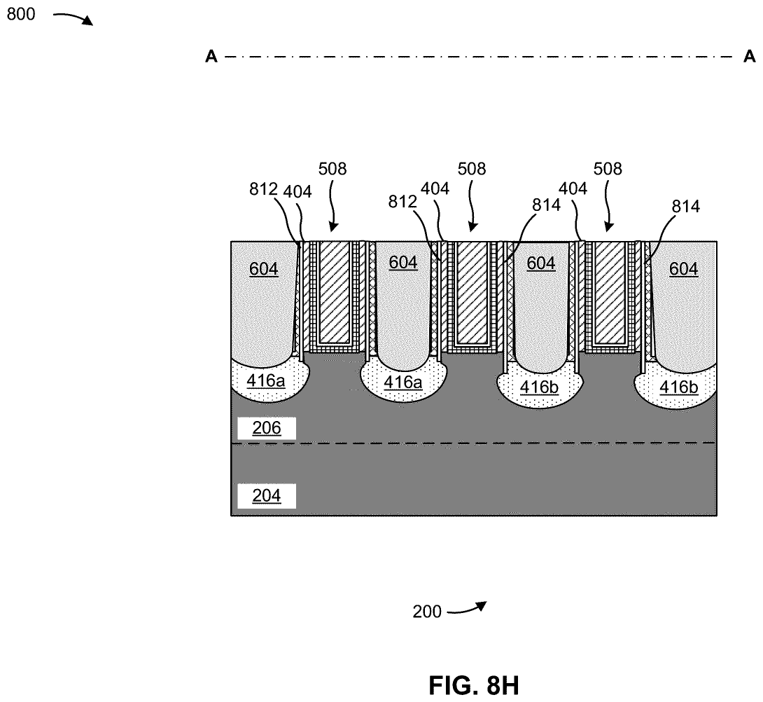

FIGS. 8A-8H are diagrams of an example implementation 800 described herein. The example implementation 8A-8H includes an alternative implementation, to the implementations of FIGS. 4A-4G, 5A-5D, and 6A-6C of forming the semiconductor device 200. In particular, the example implementation 8A-8H is similar to the example implementations 400, 500, and 600, except that sidewall protection layers 410 having different dimensions are formed in the semiconductor device 200 in the example implementation 800. This enables the source/drain regions 416 of different transistors in the semiconductor device 200 to be formed to have different dimensions, such as different channel lengths. This enables the sidewall protection layers 410 to be used to form source/drain regions 416 for transistors for different use cases and/or different applications in the same semiconductor device 200.

FIGS. 8A-8H are illustrated from the perspective of the cross-sectional plane A-A in FIG. 2 for the device region 202. Turning to FIG. 8A, the operations described in connection with the example implementation 800 are performed after the fin formation process described in connection with FIGS. 3A-3D, and after the dummy gate formation operations described in connection with FIG. 4A.

As shown in FIG. 8B, first portions of the fin structure 206 are exposed, and second portions of the fin structure 206 are covered by a masking layer 802. The masking layer 802 may include a photoresist, a hard mask layer, and/or another type of masking layer. A deposition tool 102 may be used to deposit the masking layer 802 in a PVD operation, an ALD operation, a CVD operation, a spin-coating operation, an oxidation operation, another type of deposition operation described in connection with FIG. 1, and/or another suitable deposition operation.

As further shown in FIG. 8B, a first etch operation is performed to etch the first portions of the fin structure 206 to form source/drain recesses 804 to a first depth while the masking layer 802 protects the second portions of the fin structure 206 from being etched. The first etch operation includes an anisotropic etch, which may be performed using a dry etch technique such as dry plasma-based etching. The use of the dry etch technique enables a highly directional (e.g., vertical) etching of the fin structure 206 to be performed using an etch tool 108, which enables the source/drain recesses 804 to be formed such that the sidewalls of the source/drain recesses 804 are vertical or have minimal rounding or taper. The masking layer 802 may be removed after the first etch operation.

As shown in FIG. 8C, the first portions of the fin structure 206 (and the source/drain recesses 804) are then covered with a masking layer 806, and second portions of the fin structure 206 are exposed. The masking layer 806 may include a photoresist, a hard mask layer, and/or another type of masking layer. A deposition tool 102 may be used to deposit the masking layer 806 in a PVD operation, an ALD operation, a CVD operation, a spin-coating operation, an oxidation operation, another type of deposition operation described in connection with FIG. 1, and/or another suitable deposition operation.

As further shown in FIG. 8C, a second etch operation is performed to etch the second portions of the fin structure 206 to form source/drain recesses 808 to a second depth while the masking layer 806 protects the source/drain recesses 804 in the first portions of the fin structure 206 from being etched. The second depth is greater than the first depth. The second etch operation includes an anisotropic etch, which may be performed using a dry etch technique such as dry plasma-based etching. The use of the dry etch technique enables a highly directional (e.g., vertical) etching of the fin structure 206 to be performed using an etch tool 108, which enables the source/drain recesses 808 to be formed such that the sidewalls of the source/drain recesses 808 are vertical or have minimal rounding or taper.

As shown in FIG. 8D, a protection layer 810 is formed on the semiconductor device 200 after the second etch operation. The protection layer 810 is used to form sidewall protection layers on the dummy gate structures 210. The sidewall protection layers are used to precisely control the shape or profile of the source/drain recesses 804 and 808 in subsequent etch operations.

The protection layer 810 may be conformally deposited in the source/drain recesses 804 and 808, on the sidewalls of the dummy gate structures 210 (e.g., on the seal spacer layers 402 and/or on the bulk spacer layers 404 that are on the sidewalls of the dummy gate structures 210), and/or on the top surfaces of the dummy gate structures (e.g., on the capping layer 216 of the dummy gate structures 210). A deposition tool 102 may be used to deposit the protection layer 810 in a PVD operation, an ALD operation, a CVD operation, an oxidation operation, another type of deposition operation described in connection with FIG. 1, and/or another suitable deposition operation.

As shown in FIG. 8E, a third etch operation is performed, after formation of the protection layer 810, to increase the depth of the source/drain recesses 804 from the first depth to a third depth that is greater than the first depth. The third etch operation may also increase the depth of the source/drain recesses 808 from the second depth to a fourth depth that is greater than the second depth. The fourth depth is greater than the third depth because of the second depth being greater than the first depth.

The third etch operation includes another anisotropic etch, which may be performed using a dry etch technique such as dry plasma-based etching. The use of the dry etch technique enables a highly directional (e.g., vertical) etching of the fin structure 206 to be performed using an etch tool 108, which enables the source/drain recesses 804 and 808 to be formed such that the sidewalls of the source/drain recesses 406 are vertical or have minimal rounding or taper.

As further shown in FIG. 8E, portions of the protection layer 810 are removed during the third etch operation, resulting in formation of sidewall protection layers 812 on the sides of the dummy gate structure 210 between the source/drain recesses 804, and formation of sidewall protection layers 814 on the sides of the dummy gate structure 210 between the source/drain recesses 808. The dummy gate structure 210 between a source/drain recess 804 and a source/drain recess 808 may have a sidewall protection layer 812 on the side adjacent to the source/drain recess 804, and may have a sidewall protection layer 814 on the side adjacent to the source/drain recess 808.

Bottom portions of the sidewall protection layers 814 extend further below the bottom surface of the dummy gate structures 210 (and further below the top surface of the fin structures 206 under the dummy gate structures 210) because of the fourth depth of the source/drain recesses 808 being greater than the third depth of the source/drain recesses 804. Thus, tuning the depths of the source/drain recesses 804 and 808 prior to the third etch operation enables the extension distance of the sidewall protection layers 812 and 814 to be tuned for specific use cases and/or transistor types, among other examples. In general, the deeper a source/drain recess is formed, the deeper a sidewall protection layer will extend under a dummy gate structure adjacent to the source/drain recess.

As shown in FIG. 8F, a fourth etch operation is performed, after the third etch operation, to define or reduce the channel length between source/drain regions under the dummy gate structures 210. The fourth etch operation also results in the depth of the source/drain recesses 804 being increased from the third depth to a fifth depth that is greater than the third depth. The fourth etch operation also results in the depth of the source/drain recesses 808 being increased from the fourth depth to a sixth depth that is greater than the fourth depth. In some implementations, the sixth depth is greater than the fifth depth. In some implementations, the fifth depth and the sixth depth are approximately the same depth.

The fourth etch operation includes an isotropic etch, which may be performed using a wet etch technique involving a wet etchant (e.g., a chemical etchant). The use of the wet etch technique enables an omnidirectional etching of the fin structure 206 to be performed using an etch tool 108, which enables the source/drain recesses 804 and 808 to be laterally etched. Lateral etching of the source/drain recesses 804 and 808 enables the source/drain recesses 804 and 808 to be expanded under a dummy gate structures 210, thereby enabling the channel length (e.g., the distance between source/drain recesses on opposing sides of the dummy gate structure 210) to be reduced. The sidewall protection layers 812 enable a buffer region 414a to be formed in the fin structure 206 adjacent to the source/drain recesses 804. The sidewall protection layers 814 enable a buffer region 414b to be formed in the fin structure 206 adjacent to the source/drain recesses 808.

As further shown in FIG. 8F, the source/drain recesses 804, the fin structure 206 adjacent to a source/drain recess 804, and/or the sidewall protection layers 812 may have one or more of the dimensions D2-D6 described above in connection with FIG. 4F. Moreover, source/drain recesses 804, the fin structure 206 adjacent to a source/drain recess 804, and/or the sidewall protection layers 812 may have one or more dimensions, including a dimension D7, a dimension D8, a dimension D9, a dimension D10, and/or a dimension D11, among other examples.

The dimension D7 corresponds to a width of a buffer region 414b of the fin structure 206 under a dummy gate structure 210. The dimension D8 corresponds to the shortest channel length in the fin structure 206 under the dummy gate structure 210 between source/drain recesses 808. The dimension D8 is less than the dimension D7 as a result of the lateral etching of the source/drain recesses 808 in the third etch operation, and as a result of the sidewall protection layers 814 protecting the buffer region 414b during the third etch operation. In some implementations, the dimension D8 is greater than the dimension D3. In some implementations, the dimension D3 is greater than the dimension D8. In some implementations, the dimension D8 and the dimension D3 are approximately equal.

The dimension D9 corresponds to a thickness of the buffer region 414b of the fin structure 206 between source/drain recesses 808. In some implementations, the dimension D9 is greater than the dimension D4. In some implementations, the dimension D4 is greater than the dimension D9. In some implementations, the dimension D9 and the dimension D4 are approximately equal.

The dimension D9 also corresponds to the distance that the sidewall protection layers 814 extend under the bottom surface of a dummy gate structure 210. In some implementations, the dimension D9 is included in a range of greater than 0% of the total depth of the source/drain recesses 808 (which corresponds to the dimension D10 in FIG. 8F), to approximately 50% of the total depth of the source/drain recesses 808. If the dimension D9 is 0%, the sidewall protection layers 814 do not extend below the dummy gate structure 210 and do not provide protection for etching of the buffer region 414b, which may result in the source/drain regions that are formed in the source/drain recesses 808 being in contact with residual dummy gate material. If the dimension D9 is greater than approximately 50%, the location of the shortest channel length through the fin structure 206 under the dummy gate structure 210 may be too low in the fin structure 206, and the metal gate structure that replaces the dummy gate structure 210 may not be able to control the conductivity of the channel in the fin structure 206. If the dimension D9 is in the range of greater than 0% to approximately 50%, the metal gate structure may be able to sufficiently control the conductivity of the channel in the fin structure 206, and the likelihood of the source/drain regions that are formed in the source/drain recesses 808 being in contact with residual dummy gate material is reduced. However, other values for the dimension D9, and ranges other than greater than 0% to approximately 50%, are within the scope of the present disclosure.

In some implementations, the dimension D10 is included in a range of greater than approximately 0 nanometers to approximately 100 nanometers, depending on the type of transistor being formed (e.g., a high-voltage transistor, a low-voltage transistor), a use case for the transistor (e.g., logic, power supply, memory, photodiode), and/or one or more parameters for the transistor, among other examples. However, other values for the range are within the scope of the present disclosure. In some implementations, the dimension D10 is greater than the dimension D5. In some implementations, the dimension D5 is greater than the dimension D10. In some implementations, the dimension D5 and the dimension D10 are approximately equal.

The dimension D11 corresponds to an angle between the top surface of the fin structure 206 and a sidewall of the buffer region 414b of the fin structure 206. In some implementations, the dimension D11 is included in a range of approximately 80 degrees to approximately 100 degrees. However, other values for the range are within the scope of the present disclosure.

As shown in FIG. 8G, source/drain regions 416a may be formed in the source/drain recesses 804, and source/drain regions 416b may be formed in the source/drain recesses 808. The source/drain regions 416a and 416b may be formed in a similar as the source/drain regions 416 described in connection with FIG. 4F.

As shown in FIG. 8H, additional semiconductor processing operations described in connection with FIGS. 5A-5D and/or 6A-6C may be performed to replace the dummy gate structures 210 with the gate structures 508, and to form the conductive structures 604.

As indicated above, FIGS. 8A-8H are provided as an example. Other examples may differ from what is described with regard to FIGS. 8A-8H.

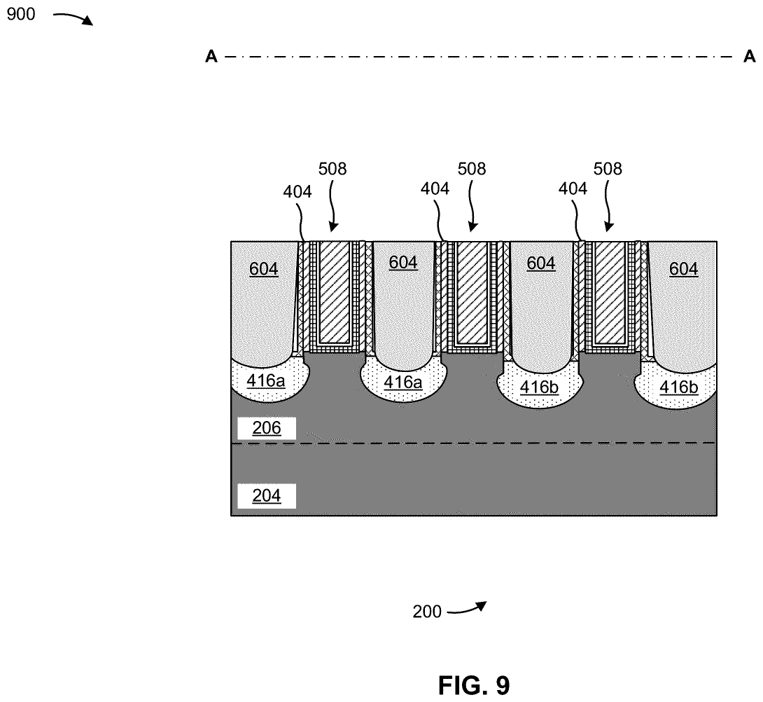

FIG. 9 is diagram of an example implementation 900 described herein. The example implementation 900 includes an alternative implementation, to the implementations of FIGS. 8A-8H. In particular, the example implementation 900 is similar to the example implementation 800, except that the sidewall protection layers 812 and 814 are removed from the semiconductor device 200 in the example implementation 900 after formation of the source/drain recesses 406. Removal of the sidewall protection layers 812 and 814 provides a greater area between the dummy gate structures 210 for forming source/drain interconnects (e.g., the conductive structures 604). This provides improved gap-filling performance for the source/drain interconnects and/or reduced resistance for the source/drain interconnects, among other examples. However, retaining the sidewall protection layers 812 and 814 in the semiconductor device 200, as in the example implementation 800, results in fewer semiconductor processing operations for the semiconductor device 200, and therefore reduced manufacturing time, cost, and resource consumption.

As indicated above, FIG. 9 is provided as an example. Other examples may differ from what is described with regard to FIG. 9.

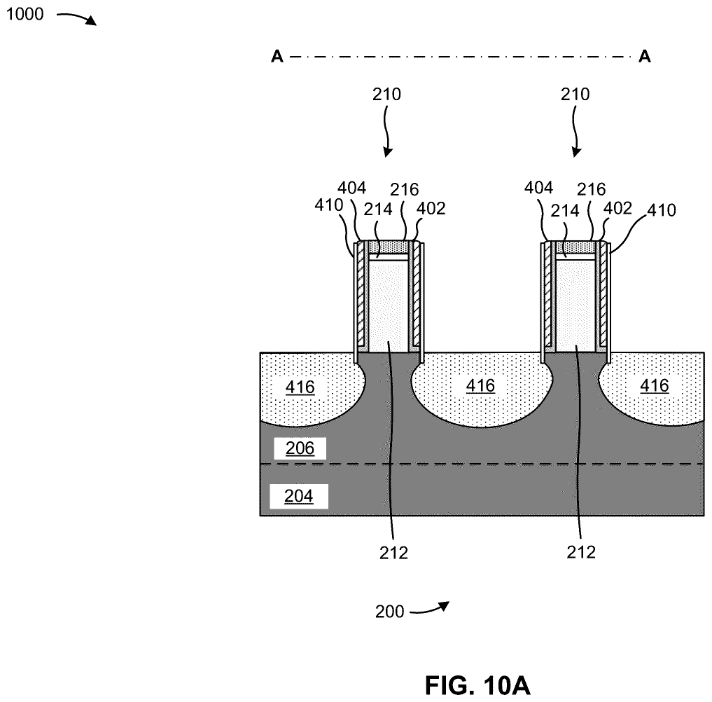

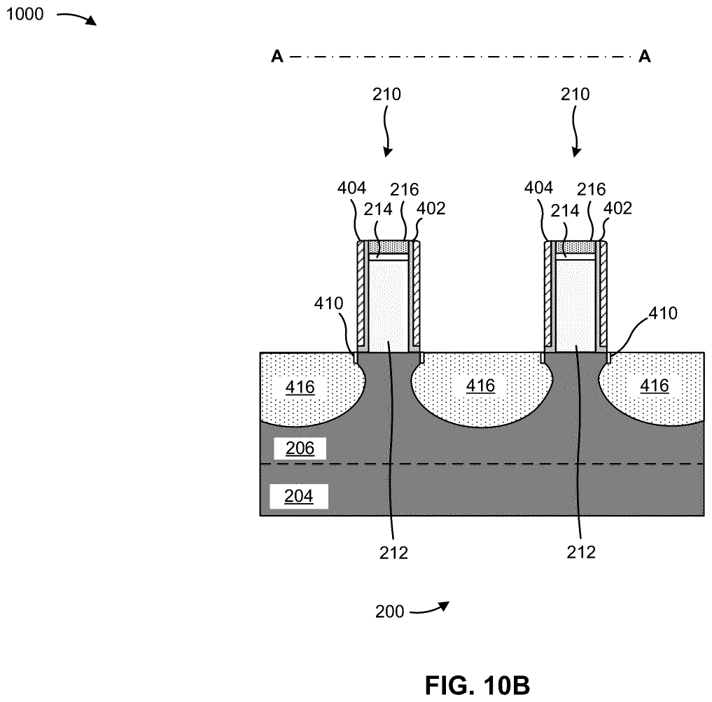

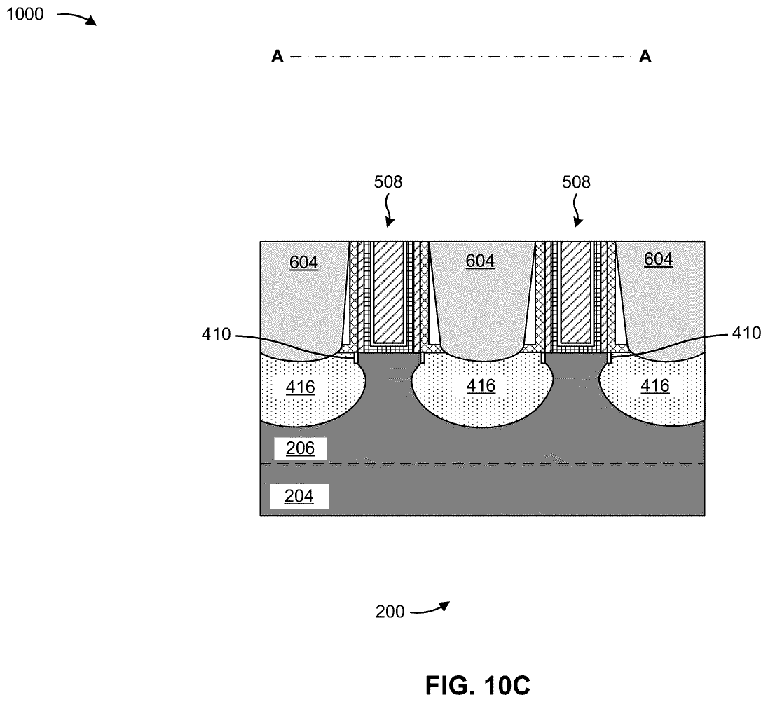

FIGS. 10A-10C are diagrams of an example implementation 1000 described herein. The example implementation 1000 includes an alternative implementation, to the implementations of FIGS. 4A-4G, 5A-5D, and 6A-6C of forming the semiconductor device 200. In particular, the example implementation 1000 is similar to the example implementations 400, 500, and 600, except that the sidewall protection layers 410 are removed from the semiconductor device 200 in the example implementation 1000 after formation of the source/drain regions 416. Removal of the sidewall protection layers 410 provides a greater area between the dummy gate structures 210 for forming source/drain interconnects (e.g., the conductive structures 604). This provides improved gap-filling performance for the source/drain interconnects and/or reduced resistance for the source/drain interconnects, among other examples. However, retaining the sidewall protection layers 410 in the semiconductor device 200, as in the example implementations 400, 500, and 600, results in fewer semiconductor processing operations for the semiconductor device 200, and therefore reduced manufacturing time, cost, and resource consumption.

FIGS. 10A-10C are illustrated from the perspective of the cross-sectional plane A-A in FIG. 2 for the device region 202. Turning to FIG. 10A, the operations described in connection with the example implementation 1000 are performed after the fin formation process described in connection with FIGS. 3A-3D, and after the dummy gate formation operations and the source/drain region formation operations described in connection with FIGS. 4A-4F.

As shown in FIG. 10B, after formation of the source/drain regions 416, the exposed portions of the sidewall protection layers 410 (e.g., that are exposed above the source/drain regions 416) are removed from the sides of the dummy gate structures 210 in the example implementation 1000. The portions of the sidewall protection layers 410 that extend along the fin structures 206 and below the dummy gate structures 210 are covered by the source/drain regions 416 and are therefore retained in the semiconductor device 200. An etch tool 108 may be used to selectively remove the exposed portions of the sidewall protection layers 410. A dry etch operation, a wet etch operation, a combination thereof, and/or another type of etch operation may be performed to remove the exposed portions of the sidewall protection layers 410.

As shown in FIG. 10C, additional semiconductor processing operations described in connection with FIGS. 5A-5D and/or 6A-6C may be performed to replace the dummy gate structures 210 with the gate structures 508, and to form the conductive structures 604.

As indicated above, FIGS. 10A-10C are provided as an example. Other examples may differ from what is described with regard to FIGS. 10A-10C.

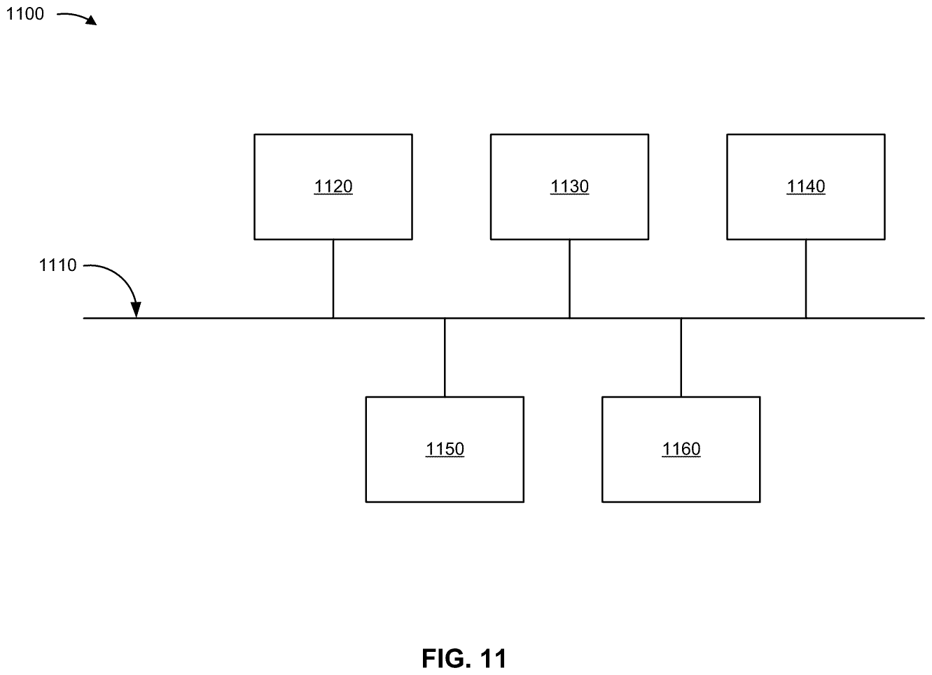

FIG. 11 is a diagram of example components of a device 1100 described herein. In some implementations, one or more of the semiconductor processing tools 102-112 and/or the wafer/die transport tool 114 may include one or more devices 1100 and/or one or more components of the device 1100. As shown in FIG. 11, the device 1100 may include a bus 1110, a processor 1120, a memory 1130, an input component 1140, an output component 1150, and/or a communication component 1160.

The bus 1110 may include one or more components that enable wired and/or wireless communication among the components of the device 1100. The bus 1110 may couple together two or more components of FIG. 11, such as via operative coupling, communicative coupling, electronic coupling, and/or electric coupling. For example, the bus 1110 may include an electrical connection (e.g., a wire, a trace, and/or a lead) and/or a wireless bus. The processor 1120 may include a central processing unit, a graphics processing unit, a microprocessor, a controller, a microcontroller, a digital signal processor, a field-programmable gate array, an application-specific integrated circuit, and/or another type of processing component. The processor 1120 may be implemented in hardware, firmware, or a combination of hardware and software. In some implementations, the processor 1120 may include one or more processors capable of being programmed to perform one or more operations or processes described elsewhere herein.

The memory 1130 may include volatile and/or nonvolatile memory. For example, the memory 1130 may include random access memory (RAM), read only memory (ROM), a hard disk drive, and/or another type of memory (e.g., a flash memory, a magnetic memory, and/or an optical memory). The memory 1130 may include internal memory (e.g., RAM, ROM, or a hard disk drive) and/or removable memory (e.g., removable via a universal serial bus connection). The memory 1130 may be a non-transitory computer-readable medium. The memory 1130 may store information, one or more instructions, and/or software (e.g., one or more software applications) related to the operation of the device 1100. In some implementations, the memory 1130 may include one or more memories that are coupled (e.g., communicatively coupled) to one or more processors (e.g., processor 1120), such as via the bus 1110. Communicative coupling between a processor 1120 and a memory 1130 may enable the processor 1120 to read and/or process information stored in the memory 1130 and/or to store information in the memory 1130.

The input component 1140 may enable the device 1100 to receive input, such as user input and/or sensed input. For example, the input component 1140 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1150 may enable the device 1100 to provide output, such as via a display, a speaker, and/or a light-emitting diode. The communication component 1160 may enable the device 1100 to communicate with other devices via a wired connection and/or a wireless connection. For example, the communication component 1160 may include a receiver, a transmitter, a transceiver, a modem, a network interface card, and/or an antenna.

The device 1100 may perform one or more operations or processes described herein. For example, a non-transitory computer-readable medium (e.g., memory 1130) may store a set of instructions (e.g., one or more instructions or code) for execution by the processor 1120. The processor 1120 may execute the set of instructions to perform one or more operations or processes described herein. In some implementations, execution of the set of instructions, by one or more processors 1120, causes the one or more processors 1120 and/or the device 1100 to perform one or more operations or processes described herein. In some implementations, hardwired circuitry may be used instead of or in combination with the instructions to perform one or more operations or processes described herein. Additionally, or alternatively, the processor 1120 may be configured to perform one or more operations or processes described herein. Thus, implementations described herein are not limited to any specific combination of hardware circuitry and software.

The number and arrangement of components shown in FIG. 11 are provided as an example. The device 1100 may include additional components, fewer components, different components, or differently arranged components than those shown in FIG. 11. Additionally, or alternatively, a set of components (e.g., one or more components) of the device 1100 may perform one or more functions described as being performed by another set of components of the device 1100.

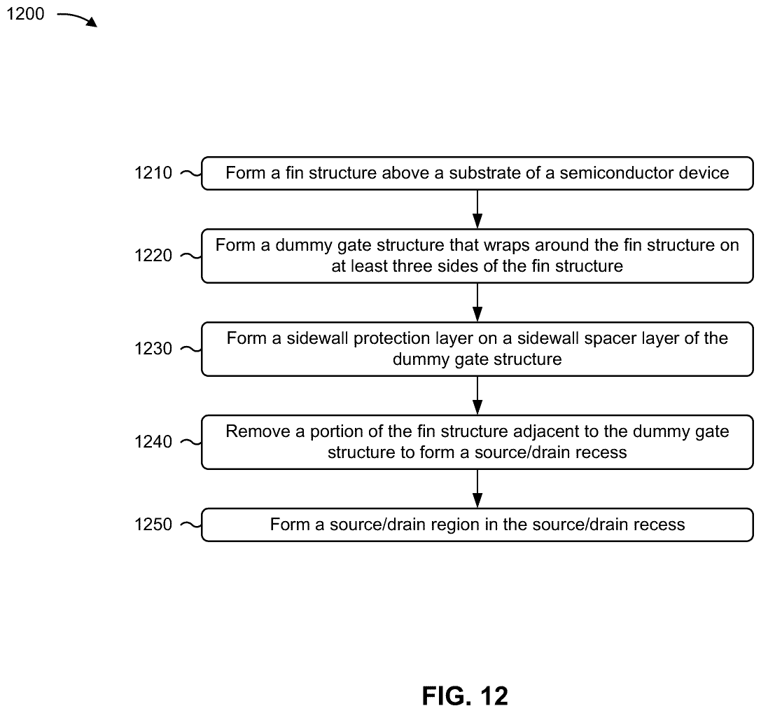

FIG. 12 is a flowchart of an example process 1200 associated with forming a semiconductor device described herein. In some implementations, one or more process blocks of FIG. 12 are performed using one or more semiconductor processing tools (e.g., one or more of the semiconductor processing tools 102-112). Additionally, or alternatively, one or more process blocks of FIG. 12 may be performed using one or more components of device 1100, such as processor 1120, memory 1130, input component 1140, output component 1150, and/or communication component 1160.

As shown in FIG. 12, process 1200 may include forming a fin structure above a substrate of a semiconductor device (block 1210). For example, one or more of the semiconductor processing tools 102-112 may be used to form a fin structure 206 above a substrate 204 of a semiconductor device 200, as described herein.

As further shown in FIG. 12, process 1200 may include forming a dummy gate structure that wraps around the fin structure on at least three sides of the fin structure (block 1220). For example, one or more of the semiconductor processing tools 102-112 may be used to form a dummy gate structure 210 that wraps around the fin structure 206 on at least three sides of the fin structure 206, as described herein.

As further shown in FIG. 12, process 1200 may include forming a sidewall protection layer on a sidewall spacer layer of the dummy gate structure (block 1230). For example, one or more of the semiconductor processing tools 102-112 may be used to form a sidewall protection layer (e.g., a sidewall protection layer 410, a sidewall protection layer 812, a sidewall protection layer 814) on a sidewall spacer layer (e.g., a seal spacer layer 402, a bulk spacer layer 404) of the dummy gate structure 210, as described herein.

As further shown in FIG. 12, process 1200 may include removing a portion of the fin structure adjacent to the dummy gate structure to form a source/drain recess (block 1240). For example, one or more of the semiconductor processing tools 102-112 may be used to remove a portion of the fin structure 206 adjacent to the dummy gate structure 210 to form a source/drain recess (e.g., a source/drain recess 406, a source/drain recess 804, a source/drain recess 808), as described herein. In some implementations, the sidewall protection layer resists etching of the fin structure 206 under the sidewall spacer layer.

As further shown in FIG. 12, process 1200 may include forming a source/drain region in the source/drain recess (block 1250). For example, one or more of the semiconductor processing tools 102-112 may be used to form a source/drain region (e.g., a source/drain region 416, a source/drain region 416a, a source/drain region 416b) in the source/drain recess, as described herein.

Process 1200 may include additional implementations, such as any single implementation or any combination of implementations described below and/or in connection with one or more other processes described elsewhere herein.

In a first implementation, process 1200 includes forming an ILD layer 504 over the source/drain region and over the sidewall protection layer.

In a second implementation, alone or in combination with the first implementation, forming the sidewall protection layer includes forming the sidewall protection layer on a top surface of the dummy gate structure 210 (e.g., on a capping layer 216 of the dummy gate structure 210) and on a top surface of the portion of the fin structure 206, where the sidewall protection layer is removed from the top surface of the dummy gate structure 210 and from the top surface of the portion of the fin structure 206 when removing the portion of the fin structure 206, and the sidewall protection layer is retained on the sidewall spacer layer of the dummy gate structure 210 after removal of the portion of the fin structure 206.

In a third implementation, alone or in combination with one or more of the first and second implementations, removing the portion of the fin structure 206 adjacent to the dummy gate structure 210 includes removing a second portion of the fin structure 206 adjacent to the dummy gate structure 210 to increase a depth of the source/drain recess from a first depth to a second depth, and where the process 1200 includes removing a first portion of the fin structure 206 adjacent to the dummy gate structure 210 to form the source/drain recess to the first depth.

In a fourth implementation, alone or in combination with one or more of the first through third implementations, removing the first portion of the fin structure 206 adjacent to the dummy gate structure 210 to form the source/drain recess to the first depth includes removing, prior to formation of the sidewall protection layer, the first portion of the fin structure 206 adjacent to the dummy gate structure 210 to form the source/drain recess to the first depth.

In a fifth implementation, alone or in combination with one or more of the first through fourth implementations, removing the first portion of the fin structure 206 adjacent to the dummy gate structure 210 to form the source/drain recess includes removing a third portion of the fin structure 206 adjacent to the dummy gate structure 210 to increase the depth of the source/drain recess from the second depth to a third depth and to increase a width of the source/drain region.

In a sixth implementation, alone or in combination with one or more of the first through fifth implementations, the first portion is removed using an anisotropic etch technique, the second portion is removed using the anisotropic etch technique, and the third portion is removed using an isotropic etch technique.

In a seventh implementation, alone or in combination with one or more of the first through sixth implementations, forming the sidewall protection layer includes forming the sidewall protection layer to a thickness that is included in a range of approximately 0.1 nanometers to approximately 15 nanometers.

In an eighth implementation, alone or in combination with one or more of the first through seventh implementations, the process 1200 includes removing at least a portion of the sidewall protection layer after removing the portion of the fin structure.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

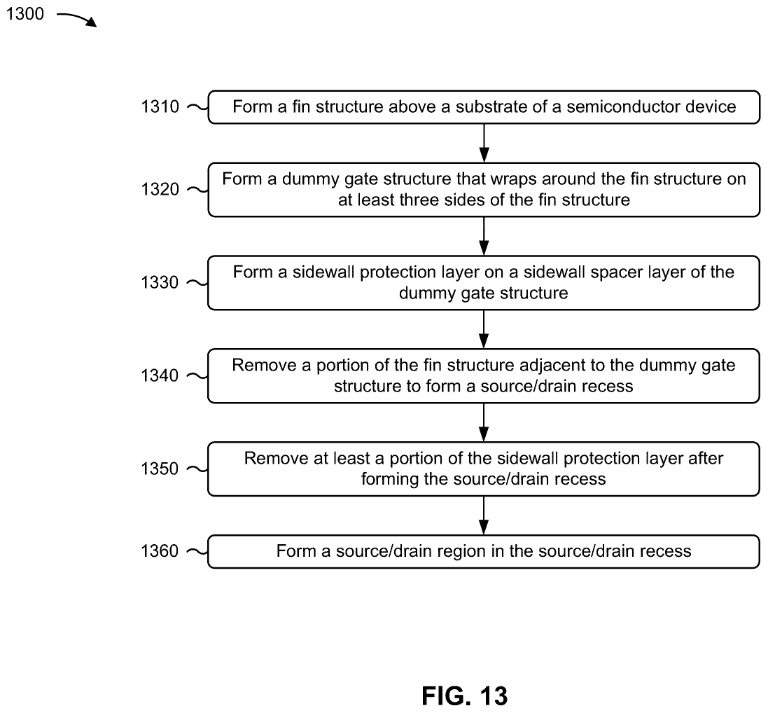

FIG. 13 is a flowchart of an example process 1300 associated with forming a semiconductor device described herein. In some implementations, one or more process blocks of FIG. 13 are performed using one or more semiconductor processing tools (e.g., one or more of the semiconductor processing tools 102-112). Additionally, or alternatively, one or more process blocks of FIG. 13 may be performed using one or more components of device 1100, such as processor 1120, memory 1130, input component 1140, output component 1150, and/or communication component 1160.

As shown in FIG. 13, process 1300 may include forming a fin structure above a substrate of a semiconductor device (block 1310). For example, one or more of the semiconductor processing tools 102-112 may be used to form a fin structure 206 above a substrate 204 of a semiconductor device 200, as described herein.

As further shown in FIG. 13, process 1300 may include forming a dummy gate structure that wraps around the fin structure on at least three sides of the fin structure (block 1320). For example, one or more of the semiconductor processing tools 102-112 may be used to form a dummy gate structure 210 that wraps around the fin structure 206 on at least three sides of the fin structure 206, as described herein.

As further shown in FIG. 13, process 1300 may include forming a sidewall protection layer on a sidewall spacer layer of the dummy gate structure (block 1330). For example, one or more of the semiconductor processing tools 102-112 may be used to form a sidewall protection layer (e.g., a sidewall protection layer 410, a sidewall protection layer 812, a sidewall protection layer 814) on a sidewall spacer layer (e.g., a seal spacer layer 402, a bulk spacer layer 404) of the dummy gate structure 210, as described herein.

As further shown in FIG. 13, process 1300 may include removing a portion of the fin structure adjacent to the dummy gate structure to form a source/drain recess (block 1340). For example, one or more of the semiconductor processing tools 102-112 may be used to remove a portion of the fin structure 206 adjacent to the dummy gate structure 210 to form a source/drain recess (e.g., a source/drain recess 406, a source/drain recess 804, a source/drain recess 808), as described herein. In some implementations, the sidewall protection layer resists etching of the fin structure 206 under the sidewall spacer layer.

As further shown in FIG. 13, process 1300 may include removing at least a portion of the sidewall protection layer after forming the source/drain recess (block 1350). For example, one or more of the semiconductor processing tools 102-112 may be used to remove at least a portion of the sidewall protection layer after forming the source/drain recess, as described herein.

As further shown in FIG. 13, process 1300 may include forming a source/drain region in the source/drain recess (block 1360). For example, one or more of the semiconductor processing tools 102-112 may be used to form a source/drain region (e.g., a source/drain region 416, a source/drain region 416a, a source/drain region 416b) in the source/drain recess, as described herein.

Process 1300 may include additional implementations, such as any single implementation or any combination of implementations described below and/or in connection with one or more other processes described elsewhere herein.

In a first implementation, removing at least the portion of the sidewall protection layer after forming the source/drain recess includes fully removing the sidewall protection layer prior to forming the source/drain region in the source/drain recess.

In a second implementation, alone or in combination with the first implementation, removing at least the portion of the sidewall protection layer after forming the source/drain recess includes removing a first portion of sidewall protection layer after forming the source/drain region in the source/drain recess, where a second portion of the sidewall protection layer is retained between the source/drain region and the fin structure 206.

In a third implementation, alone or in combination with one or more of the first and second implementations, removing the portion of the fin structure 206 adjacent to the dummy gate structure 210 includes removing a second portion of the fin structure 206 adjacent to the dummy gate structure 210 to increase a depth of the source/drain recess from a first depth to a second depth, and where the process 1300 includes removing a first portion of the fin structure 206 adjacent to the dummy gate structure 210 to form the source/drain recess to the first depth.

In a fourth implementation, alone or in combination with one or more of the first through third implementations, removing the first portion of the fin structure 206 adjacent to the dummy gate structure 210 to form the source/drain recess to the first depth includes removing, prior to formation of the sidewall protection layer, the first portion of the fin structure 206 adjacent to the dummy gate structure 210 to form the source/drain recess to the first depth.

In a fifth implementation, alone or in combination with one or more of the first through fourth implementations, the source/drain recess is a first source/drain recess, the sidewall protection layer is a first sidewall protection layer, and the process 1300 includes removing, while a masking layer 806 protects the first source/drain recess, another portion of the fin structure 206 adjacent to the dummy gate structure 210 to form a second source/drain recess to a third depth that is greater than the first depth.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

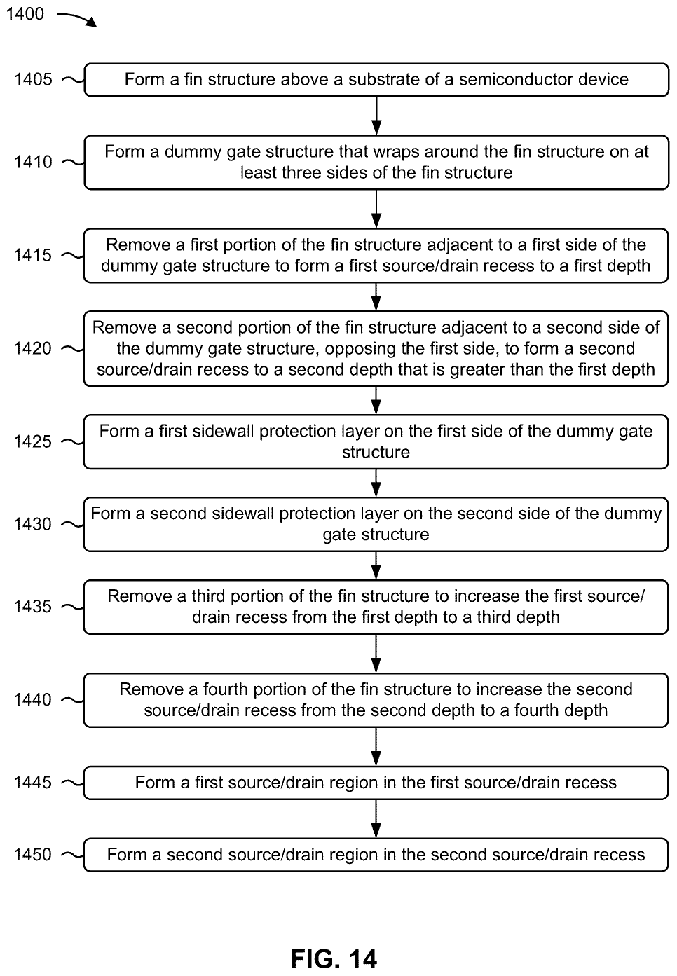

FIG. 14 is a flowchart of an example process 1400 associated with forming a semiconductor device described herein. In some implementations, one or more process blocks of FIG. 14 are performed using one or more semiconductor processing tools (e.g., one or more of the semiconductor processing tools 102-112). Additionally, or alternatively, one or more process blocks of FIG. 14 may be performed using one or more components of device 1100, such as processor 1120, memory 1130, input component 1140, output component 1150, and/or communication component 1160.

As shown in FIG. 14, process 1400 may include forming a fin structure above a substrate of a semiconductor device (block 1405). For example, one or more of the semiconductor processing tools 102-112 may be used to form a fin structure 206 above a substrate 204 of a semiconductor device 200, as described herein.

As further shown in FIG. 14, process 1400 may include forming a dummy gate structure that wraps around the fin structure on at least three sides of the fin structure (block 1410). For example, one or more of the semiconductor processing tools 102-112 may be used to form a dummy gate structure 210 that wraps around the fin structure 206 on at least three sides of the fin structure 206, as described herein.

As further shown in FIG. 14, process 1400 may include removing a first portion of the fin structure adjacent to a first side of the dummy gate structure to form a first source/drain recess to a first depth (block 1415). For example, one or more of the semiconductor processing tools 102-112 may be used to remove a first portion of the fin structure 206 adjacent to a first side of the dummy gate structure 210 to form a first source/drain recess 804 to a first depth, as described herein.

As further shown in FIG. 14, process 1400 may include removing a second portion of the fin structure adjacent to a second side of the dummy gate structure, opposing the first side, to form a second source/drain recess to a second depth that is greater than the first depth (block 1420). For example, one or more of the semiconductor processing tools 102-112 may be used to remove a second portion of the fin structure 206 adjacent to a second side of the dummy gate structure 210, opposing the first side, to form a second source/drain recess 808 to a second depth that is greater than the first depth, as described herein.

As further shown in FIG. 14, process 1400 may include forming a first sidewall protection layer on the first side of the dummy gate structure (block 1425). For example, one or more of the semiconductor processing tools 102-112 may be used to form a first sidewall protection layer 812 on the first side of the dummy gate structure 210, as described herein. In some implementations, the first sidewall protection layer 812 extends into the first source/drain recess 804.

As further shown in FIG. 14, process 1400 may include forming a second sidewall protection layer on the second side of the dummy gate structure (block 1430). For example, one or more of the semiconductor processing tools 102-112 may be used to form a second sidewall protection layer 814 on the second side of the dummy gate structure 210, as described herein. In some implementations, the second sidewall protection layer 814 extends into the second source/drain recess 808 to a lower depth in the semiconductor device 200 than the first sidewall protection layer 812.

As further shown in FIG. 14, process 1400 may include removing a third portion of the fin structure to increase the first source/drain recess from the first depth to a third depth (block 1435). For example, one or more of the semiconductor processing tools 102-112 may be used to remove a third portion of the fin structure 206 to increase the first source/drain recess 804 from the first depth to a third depth, as described herein. In some implementations, the first sidewall protection layer 812 resists etching of the fin structure 206 under the first sidewall protection spacer layer 812.

As further shown in FIG. 14, process 1400 may include removing a fourth portion of the fin structure to increase the second source/drain recess from the second depth to a fourth depth (block 1440). For example, one or more of the semiconductor processing tools 102-112 may be used to remove a fourth portion of the fin structure 206 to increase the second source/drain recess 808 from the second depth to a fourth depth, as described herein. In some implementations, the second sidewall protection layer 814 resists etching of the fin structure 206 under the second sidewall protection spacer layer 814.

As further shown in FIG. 14, process 1400 may include forming a first source/drain region in the first source/drain recess (block 1445). For example, one or more of the semiconductor processing tools 102-112 may be used to form a first source/drain region 416a in the first source/drain recess 804, as described herein.

As further shown in FIG. 14, process 1400 may include forming a second source/drain region in the second source/drain recess (block 1450). For example, one or more of the semiconductor processing tools 102-112 may be used to form a second source/drain region 416b in the second source/drain recess 808, as described herein.

Process 1400 may include additional implementations, such as any single implementation or any combination of implementations described below and/or in connection with one or more other processes described elsewhere herein.

In a first implementation, process 1400 includes fully removing the first sidewall protection layer prier 812 prior to forming the first source/drain region 416a in the first source/drain recess 804.

In a second implementation, alone or in combination with the first implementation, process 1400 includes removing a first portion of a first sidewall protection layer 812 after forming the first source/drain region 416a in the first source/drain recess 804, where a second portion of the first sidewall protection layer 812 is retained between the first source/drain region 416a and the fin structure 206.

In a third implementation, alone or in combination with one or more of the first and second implementations, forming the first source/drain region 416a in the first source/drain recess 804 includes forming the first source/drain region 416a on a portion of the first sidewall protection layer 812 in the first source/drain recess 416a.

In a fourth implementation, alone or in combination with one or more of the first through third implementations, process 1400 includes removing a fifth portion of the fin structure 206 to increase a lateral width of the first source/drain recess 804, where the first sidewall protection layer 812 protects a sixth portion of the fin structure 206 under the dummy gate structure 210 from lateral etching.

In a fifth implementation, alone or in combination with one or more of the first through fourth implementations, removing the second portion of the fin structure 206 includes removing, while a masking layer 806 protects the first source/drain recess 804, the second portion of the fin structure 206.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, a sidewall protection layer is formed on sidewall spacers of a dummy gate structure of a semiconductor device prior to etching an underlying fin structure to form a source/drain recess. The sidewall protection layer enables the profile of the source/drain recess to be precisely controlled so that etching into residual dummy gate material near the source/drain recess is minimized or prevented. The sidewall protection layer may be removed or retained in the semiconductor device after formation of the source/drain recess. The sidewall protection layer reduces the likelihood of the source/drain regions of the semiconductor device contacting the metal gate structures of the semiconductor device after the dummy gate structures are replaced with the metal gate structures. Thus, the sidewall protection layer reduces the likelihood of electrical shorting between the source/drain regions and the metal gate structures. This may reduce the rate and/or likelihood of defect formation in the semiconductor device and/or may increase the yield of fin-based transistors in the semiconductor device, among other examples.

As described in greater detail above, some implementations described herein provide a semiconductor device. The semiconductor device includes a fin structure extending above a substrate. The semiconductor device includes a gate structure wrapping around at least three sides of the fin structure. The semiconductor device includes a source/drain region on the fin structure and adjacent to a side of the gate structure. The semiconductor device includes a sidewall spacer layer on the side of the gate structure. The semiconductor device includes a sidewall protection layer on the sidewall spacer layer, where the sidewall protection layer extends below a bottom surface of a portion of the gate structure that is on the fin structure.

As described in greater detail above, some implementations described herein provide a method. The method includes forming a fin structure above a substrate of a semiconductor device. The method includes forming a dummy gate structure that wraps around the fin structure on at least three sides of the fin structure. The method includes forming a sidewall protection layer on a sidewall spacer layer of the dummy gate structure. The method includes removing a portion of the fin structure adjacent to the dummy gate structure to form a source/drain recess, where the sidewall protection layer resists etching of the fin structure under the sidewall spacer layer. The method includes forming a source/drain region in the source/drain recess.

As described in greater detail above, some implementations described herein provide a method. The method includes forming a fin structure above a substrate of a semiconductor device. The method includes forming a dummy gate structure that wraps around the fin structure on at least three sides of the fin structure. The method includes forming a sidewall protection layer on a sidewall spacer layer of the dummy gate structure. The method includes removing a portion of the fin structure adjacent to the dummy gate structure to form a source/drain recess, where the sidewall protection layer resists etching of the fin structure under the sidewall spacer layer. The method includes removing at least a portion of the sidewall protection layer after forming the source/drain recess. The method includes forming a source/drain region in the source/drain recess.

As described in greater detail above, some implementations described herein provide a method. The method includes forming a fin structure above a substrate of a semiconductor device. The method includes forming a dummy gate structure that wraps around the fin structure on at least three sides of the fin structure. The method includes removing a first portion of the fin structure adjacent to a first side of the dummy gate structure to form a first source/drain recess to a first depth. The method includes removing a second portion of the fin structure adjacent to a second side of the dummy gate structure, opposing the first side, to form a second source/drain recess to a second depth that is greater than the first depth. The method includes forming a first sidewall protection layer on the first side of the dummy gate structure, where the first sidewall protection layer extends into the first source/drain recess. The method includes forming a second sidewall protection layer on the second side of the dummy gate structure, where the second sidewall protection layer extends into the second source/drain recess to a lower depth in the semiconductor device than the first sidewall protection layer. The method includes removing a third portion of the fin structure to increase the first source/drain recess from the first depth to a third depth, where the first sidewall protection layer resists etching of the fin structure under the first sidewall spacer layer. The method includes removing a fourth portion of the fin structure to increase the second source/drain recess from the second depth to a fourth depth, where the second sidewall protection layer resists etching of the fin structure under the second sidewall spacer layer. The method includes forming a first source/drain region in the first source/drain recess. The method includes forming a second source/drain region in the second source/drain recess.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a fin structure extending above a substrate;
a gate structure wrapping around at least three sides of the fin structure;
a source/drain region on the fin structure and adjacent to a side of the gate structure;
a sidewall spacer layer on the side of the gate structure; and
a sidewall protection layer on the sidewall spacer layer,
wherein the sidewall protection layer extends below a bottom surface of a portion of the gate structure that is on the fin structure.

2. The semiconductor device of claim 1, wherein a portion of the sidewall protection layer, that is below the bottom surface of the portion of the gate structure that is on the fin structure, is between the gate structure and the source/drain region.

3. The semiconductor device of claim 1, wherein a portion of the sidewall protection layer, that is below the bottom surface of the portion of the gate structure that is on the fin structure, is also below a top surface of the fin structure.

4. The semiconductor device of claim 1, wherein the sidewall protection layer extends below a bottom surface of the gate structure by a distance that is included in a range of greater than 0% of a depth of the source/drain region, relative to the bottom surface of the gate structure, to approximately 50% of the depth of the source/drain region.

5. The semiconductor device of claim 1, wherein the sidewall protection layer comprises at least one of:
a polymer material,
a silicon oxide (SiOₓ) material,
a silicon nitride (SiₓN_{y}) material,
a silicon carbonitride (SiCN) material,
a silicon oxynitride (SiON) material, or
a silicon oxycarbonitride (SiOCN) material.

6. The semiconductor device of claim 1, wherein the sidewall spacer layer is a first sidewall spacer layer;
wherein the sidewall protection layer is a first sidewall protection layer; and
wherein the semiconductor device further comprises:
a second sidewall spacer layer
on another side of the gate structure opposing the side; and
a second sidewall protection layer,
wherein the first sidewall protection layer extends below the bottom surface of the portion of the gate structure by a first distance,
wherein the second sidewall protection layer extends below the bottom surface of the portion of the gate structure by a second distance, and
wherein the second distance is greater than the first distance.

7. A method, comprising:
forming a fin structure above a substrate of a semiconductor device;
forming a dummy gate structure that wraps around the fin structure on at least three sides of the fin structure;
forming a sidewall protection layer on a sidewall spacer layer of the dummy gate structure;
removing a portion of the fin structure adjacent to the dummy gate structure to form a source/drain recess,
wherein the sidewall protection layer resists etching of the fin structure under the sidewall spacer layer; and
forming a source/drain region in the source/drain recess.

8. The method of claim 7, further comprising:
forming an interlayer dielectric (ILD) layer over the source/drain region and over the sidewall protection layer.

9. The method of claim 7, wherein forming the sidewall protection layer comprises:
forming the sidewall protection layer on a top surface of the dummy gate structure and on a top surface of the portion of the fin structure,
wherein the sidewall protection layer is removed from the top surface of the dummy gate structure and from the top surface of the portion of the fin structure when removing the portion of the fin structure, and
wherein the sidewall protection layer is retained on the sidewall spacer layer of the dummy gate structure after removal of the portion of the fin structure.

10. The method of claim 7, wherein removing the portion of the fin structure adjacent to the dummy gate structure comprises:
removing a second portion of the fin structure adjacent to the dummy gate structure to increase a depth of the source/drain recess from a first depth to a second depth; and
wherein the method further comprises:
removing a first portion of the fin structure adjacent to the dummy gate structure to form the source/drain recess to the first depth.

11. The method of claim 10, wherein removing the first portion of the fin structure adjacent to the dummy gate structure to form the source/drain recess to the first depth comprises:
removing, prior to formation of the sidewall protection layer, the first portion of the fin structure adjacent to the dummy gate structure to form the source/drain recess to the first depth.

12. The method of claim 10, wherein removing the first portion of the fin structure adjacent to the dummy gate structure to form the source/drain recess comprises:
removing a third portion of the fin structure adjacent to the dummy gate structure to increase the depth of the source/drain recess from the second depth to a third depth and to increase a width of the source/drain region.

13. The method of claim 12, wherein the first portion is removed using an anisotropic etch technique;
wherein the second portion is removed using the anisotropic etch technique; and
wherein the third portion is removed using an isotropic etch technique.

14. The method of claim 7, further comprising:
removing at least a portion of the sidewall protection layer after removing the portion of the fin structure.

15. A method, comprising:
forming a fin structure above a substrate of a semiconductor device;
forming a dummy gate structure that wraps around the fin structure on at least three sides of the fin structure;
removing a first portion of the fin structure adjacent to a first side of the dummy gate structure to form a first source/drain recess to a first depth;
removing a second portion of the fin structure adjacent to a second side of the dummy gate structure, opposing the first side, to form a second source/drain recess to a second depth that is greater than the first depth;
forming a first sidewall protection layer on the first side of the dummy gate structure,
wherein the first sidewall protection layer extends into the first source/drain recess;
forming a second sidewall protection layer on the second side of the dummy gate structure,
wherein the second sidewall protection layer extends into the second source/drain recess to a lower depth in the semiconductor device than the first sidewall protection layer;
removing a third portion of the fin structure to increase the first source/drain recess from the first depth to a third depth,
wherein the first sidewall protection layer resists etching of the fin structure under the first sidewall spacer layer;
removing a fourth portion of the fin structure to increase the second source/drain recess from the second depth to a fourth depth,
wherein the second sidewall protection layer resists etching of the fin structure under the second sidewall spacer layer;
forming a first source/drain region in the first source/drain recess; and
forming a second source/drain region in the second source/drain recess.

16. The method of claim 15, further comprising:
fully removing the first sidewall protection layer prior to forming the first source/drain region in the first source/drain recess.

17. The method of claim 16, further comprising:
removing a first portion of a first sidewall protection layer after forming the first source/drain region in the first source/drain recess,
wherein a second portion of the first sidewall protection layer is retained between the first source/drain region and the fin structure.

18. The method of claim 15, wherein forming the first source/drain region in the first source/drain recess comprises:
forming the first source/drain region on a portion of the first sidewall protection layer in the first source/drain recess.

19. The method of claim 15, further comprising:
removing a fifth portion of the fin structure to increase a lateral width of the first source/drain recess,
wherein the first sidewall protection layer protects a sixth portion of the fin structure under the dummy gate structure from lateral etching.

20. The method of claim 15, wherein removing the second portion of the fin structure comprises:
removing, while a masking layer protects the first source/drain recess, the second portion of the fin structure.
